(19) United States
(12) Patent Application Publication
(10) Pub. No.: US 2016/0376699 A1
(43) Pub. Date: Dec. 29, 2016

(54) SUBSTRATE PROCESSING APPARATUS, AND STORAGE MEDIUM

(71) Applicant: HITACHI KOKUSAI ELECTRIC INC., Tokyo (JP)

(72) Inventors: Takafumi SASAKI, Toyama-shi (JP); Takatomo YAMAGUCHI, Toyama-shi (JP)

(73) Assignee: HITACHI KOKUSAI ELECTRIC INC., Tokyo (JP)

(21) Appl. No.: 15/187,300

(22) Filed: Jun. 20, 2016

(30) Foreign Application Priority Data
Jun. 26, 2015 (JP) 2015-128385

(51) Int. Cl. C23C 16/44; C23C 16/455; H01L 21/02; C23C 16/50; H01J 37/32; C23C 16/52; C23C 16/34

(52) U.S. Cl. CPC C23C 16/4401; C23C 16/52; C23C 16/45523; C23C 16/345; C23C 16/45542; C23C 16/45544; C23C 16/50; H01J 37/32357; H01J 37/32449; H01J 37/32862; H01J 37/32522; C23C 16/45546; H01L 21/0217; H01L 21/02274; H01J 2237/327; H01J 2237/3321; H01J 2237/3323

(57) ABSTRACT

A substrate processing apparatus includes a gas supply part configured to supply at least one of a film-forming gas, a first inert gas, and a second inert gas supplied at a temperature higher than that of the first inert gas into a process chamber in which a substrate is processed; and a control part configured to control the gas supply part to perform a film-forming process of supplying the film-forming gas and the first inert gas from the gas supply part into the process chamber to process the substrate, and to control a deposited film removing process of directly supplying the second inert gas having a temperature higher than that of the first inert gas from the gas supply part to the process chamber, in a state where there is no substrate in the process chamber, to remove a deposited film deposited within the process chamber.

### CROSS-REFERENCE TO RELATED APPLICATION(S)

This application is based upon and claims the benefit of priority from Japanese Patent Application No. 2015-128385, filed on Jun. 26, 2015, the entire contents of which are incorporated herein by reference.

### TECHNICAL FIELD

The present disclosure relates to a substrate processing apparatus and a non-transitory computer-readable storage medium.

### BACKGROUND

As one of the manufacturing processes of a semiconductor device, there is a processing procedure of supplying a process gas and a reaction gas to a substrate to form a film on the substrate.

Recently, semiconductor devices tend to be highly integrated and pattern sizes have been remarkably miniaturized, making it difficult to uniformly form a film on a substrate.

In order to enhance the uniformity of films formed on a substrate, it is necessary to uniformly supply a process gas to a process surface of the substrate. However, when the substrate processing is repeatedly performed several times, byproducts may be attached to an inner wall surface of a supply part for supplying a gas or an inner wall surface of a process chamber in which the substrate is processed, and become particles which can adversely affect the characteristics of a film formed on the substrate. A technique of removing the byproduct attached to the inner wall surface by causing cracks on a deposited film and removing the cracked deposited film from the inner wall surface through supplying a purge gas from an outer side of the process chamber has been known in the art.

### SUMMARY

The present disclosure provides some embodiments of a technique of enhancing uniformity in processing a substrate.

According to one embodiment of the present disclosure, there is provided a technique including: a film forming process of supplying at least a film-forming gas and a first inert gas onto a substrate within a process chamber; and a deposited film removing process of supplying a second inert gas having a temperature higher than that of the first inert gas directly into the process chamber, to remove a deposited film deposited within the process chamber by the film forming process.

### BRIEF DESCRIPTION OF THE DRAWINGS

FIG. 1 is a view illustrating a schematic configuration of a substrate processing apparatus appropriately used in a first embodiment of the present disclosure, in which a longitudinal cross-sectional view of a processing furnace part is illustrated.

FIG. 2 is a flowchart of substrate processing of the present disclosure.

FIG. 3 is a flowchart of a film forming step of the present disclosure.

FIG. 4 is a view illustrating a schematic configuration of a controller of a substrate processing apparatus appropriately used in the present disclosure.

FIG. 5 is a graph illustrating a relationship of a coefficient of linear expansion and a temperature among a silicon nitride film, stainless steel, and quartz.

FIG. 6 is a view illustrating a sequence in substrate processing appropriately used in the first embodiment of the present disclosure.

FIG. 7 is a view illustrating a third gas supply system of a substrate processing apparatus appropriately used in modification 1 of the present disclosure.

FIG. 8 is a view illustrating a sequence in substrate processing appropriately used in modification 1 of the present disclosure.

FIG. 9 is a view illustrating a third gas supply system of a substrate processing apparatus appropriately used in modification 2 of the present disclosure.

FIG. 10 is a view illustrating a sequence in substrate processing appropriately used in modification 2 of the present disclosure.

FIG. 11 is a view illustrating a sequence in substrate processing appropriately used in modification 3 of the present disclosure.

FIGS. 12A and 12B are views illustrating sequences in substrate processing appropriately used in modification 4 of the present disclosure, wherein FIG. 12A is a view of a sequence illustrating a case in which a supply temperature of a heated purge gas is gradually lowered and FIG. 12B is a view of a sequence illustrating a case in which a supply temperature of a heated purge gas is lowered by stages.

FIG. 13 is a view illustrating a schematic configuration of a substrate processing apparatus appropriately used in a second embodiment of the present disclosure, in which a longitudinal cross-sectional view of a processing furnace part is illustrated.

FIG. 14 is a view illustrating a schematic configuration of a substrate processing apparatus appropriately used in a third embodiment of the present disclosure, in which a longitudinal cross-sectional view of a processing furnace part is illustrated.

FIG. 15 is a view illustrating a schematic configuration of a substrate processing apparatus appropriately used in a fourth embodiment of the present disclosure, in which a longitudinal cross-sectional view of a processing furnace part is illustrated.

### DETAILED DESCRIPTION

### First Embodiment

Hereinafter, a first embodiment of the present disclosure will be described.

### (1) Configuration of Substrate Processing Apparatus

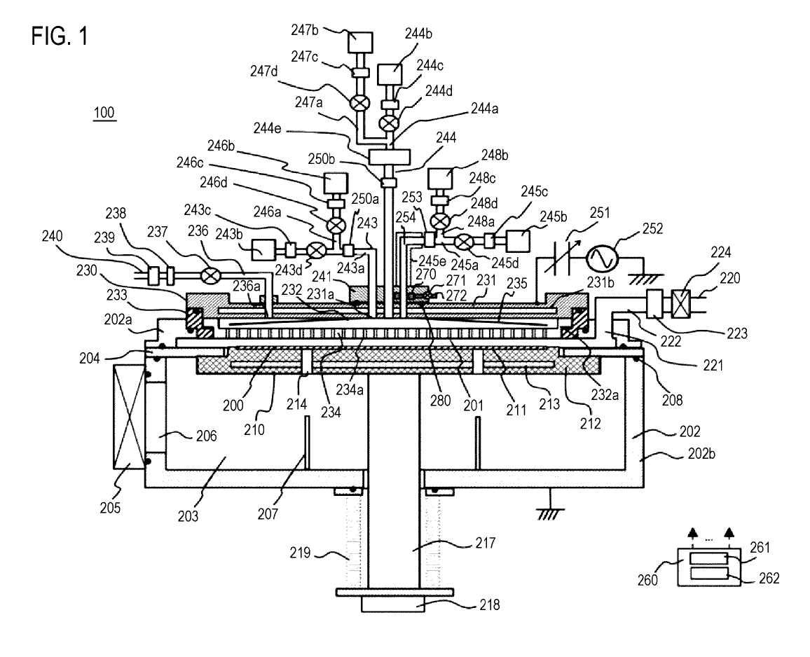

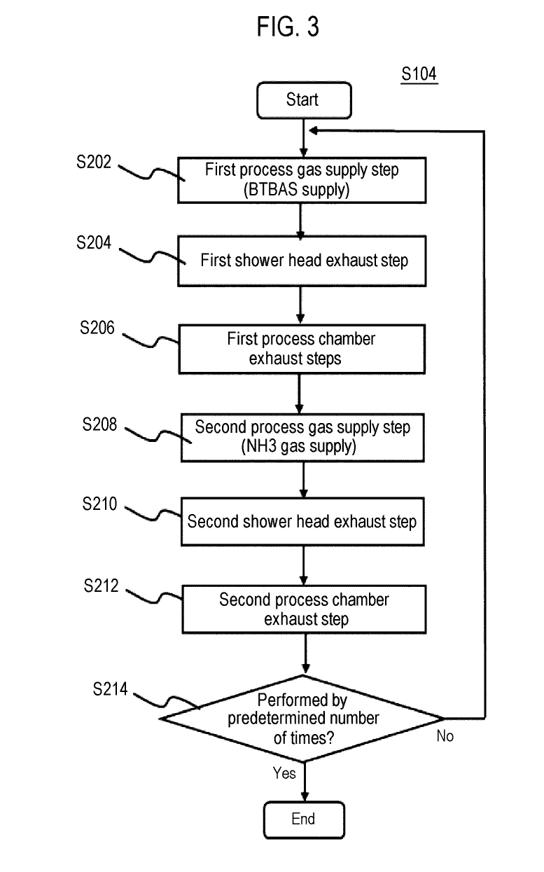

A first embodiment of a substrate processing apparatus according to the present disclosure will be described with reference to FIGS. 1 to 3. Further, as illustrate in FIG. 1, the substrate processing apparatus according to this embodiment is an apparatus in which a thin film is formed on a substrate, and is configured as a single-wafer type substrate processing apparatus which processes substrates one by one at a time.

### (Process Chamber)

As illustrated in FIG. 1, the substrate processing apparatus 100 includes a process vessel 202. The process vessel 202 is configured as, for example, a flat airtight vessel having a circular cross-section. Further, a side wall or a lower wall of the process vessel 202 is formed of a metal material such as, aluminum (A1) or stainless steel (SUS). In the process vessel 202, a process chamber 201 where a wafer 200 (e.g., a silicon wafer) is processed as a substrate, and a transfer space 203 are formed. The process vessel 202 is configured by an upper vessel 202a and a lower vessel 202b, and a shower head 230 as a ceiling part. A partition plate 204 is installed between the upper vessel 202a and the lower vessel 202b. A space, which is surrounded by the upper process vessel 202a and the shower head 230 and located above the partition plate 204, is referred to as a process chamber space, and a space, which is surrounded by the lower vessel 202b and below the partition plate, is referred to as a transfer space. A component, which is configured by the upper process vessel 202a and the shower head 230 and surrounds the process space, is referred to as the process chamber 201. In addition, a component, which surrounds the transfer space, is referred to as a transfer chamber 203 within the process chamber. An O-ring 208 configured to seal the interior of the process vessel 202 is installed between the previously described components.

A substrate loading/unloading port 206 adjacent to a gate valve 205 is installed on a side surface of the lower vessel 202b, and the wafer 200 moves into and out of a transfer chamber (not shown) through the substrate loading/unloading port 206. A plurality of lift pins 207 are installed at a bottom portion of the lower vessel 202b. Further, the lower vessel 202b is grounded.

A substrate support part 210 configured to support the wafer 200 is installed in the process chamber 201. The substrate support part 210 mainly includes a mounting surface 211 on which the wafer 200 is mounted, a mounting table 212 having the mounting surface 211 on a surface of the mounting table 212, and a susceptor heater 213 as a heating source included in the substrate mounting table 212. Through holes 214 through which the lift pins 207 pass are formed in the substrate mounting table 212 at positions corresponding to the lift pins 207, respectively.

The substrate mounting table 212 is supported by a shaft 217. The shaft 217 passes through a bottom portion of the process vessel 202 and is connected to an elevation mechanism 218 outside the process vessel 202. By operating the elevation mechanism 218 to elevate or lower the shaft 217 and the support table 212, the wafer 200 mounted on the substrate mounting surface 211 can be elevated or lowered. Further, a periphery of a lower end portion of the shaft 217 is covered with a bellows 219, and thus, the inside of the process vessel 202 is kept airtight.

The substrate mounting table 212 is lowered to the substrate support table such that the substrate mounting surface 211 reaches a position (wafer transfer position) of the substrate loading/unloading port 206 when the wafer 200 is transferred, and is elevated until the wafer 200 reaches a processing position (wafer processing position) within the process chamber 201, as shown in FIG. 1, when the wafer 200 is processed.

Specifically, when the substrate mounting table 212 is lowered to the wafer transfer position, an upper end portion of the lift pins 207 protrudes from an upper surface of the substrate mounting surface 211 and the lift pin 207 supports the wafer 200 from below. Further, when the substrate mounting table 212 is elevated to the wafer processing position, the lift pins 207 are buried from the upper surface of the substrate mounting surface 211 and the substrate mounting surface 211 supports the wafer 200 from below. In addition, since the lift pins 207 are in direct contact with the wafer 200, the lift pins 207 are preferably formed of a material such as, quartz or alumina.

### (Gas Introduction Part)

A gas introduction part 241 for supplying various gases into the process chamber 201 is formed on an upper surface (ceiling wall) of a shower head 230 described later, installed in an upper portion of the process chamber 201. A configuration of a gas supply system connected to the gas introduction part 241 will be described later.

### (Shower Head)

The shower head 230, which is a gas dispersing mechanism communicating with the process chamber 201, is installed between the gas introduction part 241 and the process chamber 201. The gas introduction part 241 is connected to a lid 231 of the shower head 230. A gas introduced from the gas introduction part 241 is supplied to a buffer space which is a space within a buffer chamber 232 of the shower head 230 through a hole 231a formed on the lid 231. The buffer chamber 232 is formed of the lid 231 and a dispersion plate 234 described later.

The lid 231 of the shower head is formed of a conductive metal and used as an electrode for generating plasma within the buffer space of the buffer chamber 232 or the process chamber 201. An insulating block 233 is installed between the lid 231 and the upper vessel 202a to insulate the lid 231 and the upper vessel 202a from each other. In addition, a resistance heater 231b as a shower head heating part is installed in the lid 231.

The shower head 230 includes the dispersion plate 234 for dispersing a gas introduced from the gas introduction part 241, between the buffer space of the buffer chamber 232 and a process space of the process chamber 201. A plurality of through holes 234a (also referred to as a group of through holes 234a) is formed in the dispersion plate 234. The dispersion plate 234 is disposed to face the substrate mounting surface 211. The dispersion plate has a convex shape portion in which the through holes 234a are formed and a flange portion installed around the convex shape portion, and the flange portion is supported by the insulating block 233.

A gas guide 235 for forming a flow of a supplied gas is installed in the buffer chamber 232. The gas guide 235 has a circular truncated conic shape having a diameter increased in a direction toward the dispersion plate 234 from the hole 231a as an apex. A diameter of a lower end of the gas guide 235 in a horizontal direction is formed in an outer periphery of the outermost periphery of the group of through holes 234a.

### (First Exhaust System)

An exhaust pipe 236 is connected to an upper portion of the buffer chamber 232 through a shower head exhaust hole 236a. A valve 237 for switching ON/OFF of the exhaust, a pressure regulator 238 such as an auto pressure controller (APC) for controlling the interior of the exhaust buffer chamber 232 to have a predetermined pressure, and a vacuum pump 239 are sequentially connected in series to the exhaust pipe 236.

Since the exhaust hole 236a is formed at the lid 231 of the shower head positioned above the gas guide 235, it is configured such that a gas flows in a shower head exhaust step described later. An inert gas supplied through the hole 231a is dispersed by the gas guide 235 and flows to the center of a space and a lower side of the buffer chamber 232. Thereafter, the inert gas is returned from an end portion of the gas guide 235 and exhausted through the exhaust hole 236a. The exhaust pipe 236, the valve 237, and the pressure regulator 238 are mainly collectively referred to as a first exhaust system 240. Also, it may be considered that the vacuum pump 239 is included in the first exhaust system 240.

### (Gas Supply Part)

A first gas supply pipe 243a, a second gas supply pipe 244a, and a third gas supply pipe 245a are connected to the gas introduction part 241 connected to the lid 231 of the shower head 230 through an O-ring 280 as a sealing member for preventing gas leakage. The second gas supply pipe 244a is connected through a remote plasma unit 244e. Further, an annular cooling channel 270 through which a cooling medium flows to suppress the dissolution of the O-ring 280 is installed in the gas introduction part 241. A cooling medium supply valve 271 for controlling the supply of a cooling medium, and a cooling pipe 272 are connected to the cooling channel 270. As illustrated in FIG. 1, the cooling channel 270 is installed on an inner side of a diameter of the O-ring 280 in an annular direction of the diameter of the O-Ring 280 to surround an outer side of at least the third gas supply pipe 245a described later in an annular direction of the diameter of the O-Ring 280. With this disposition, even when a heated purge gas having a high temperature described later is supplied, it can be cooled before heat is transferred to the O-ring 280, suppress the O-ring 280 from being dissolved.

Further, the cooling channel 270 is not limited to the disposition in which it is installed to surround the third gas supply pipe 245a as described above, and the cooling flow channel 270 may also be installed on an inner side of the O-ring 280 in the annular direction to surround an outer side of the first gas supply pipe 243a, the second gas supply pipe 244a, and the third gas supply pipe 245a in the annular direction.

Also, the sealing member is not limited to the O-ring 280 and a meal seal such as a metal gasket may be used as the sealing member.

A first element-containing gas as a precursor gas is mainly supplied from the first gas supply system 243 including the first gas supply pipe 243a, and a second element-containing gas as a reaction gas is mainly supplied from the second gas supply system 244 including the second gas supply pipe 244a. From the third gas supply system 245 including the third gas supply pipe 245a, an inert gas is mainly supplied when the wafer is processed, and a cleaning gas is mainly supplied when the process chamber 201 is cleaned.

### (First Gas Supply System)

A first gas supply source 243b, a mass flow controller (MFC) 243c, which is a flow rate controller (flow rate control part), and a valve 243d, which is an opening/closing valve, are installed in the first gas supply pipe 243a in this order from an upstream direction.

A gas containing a first element (hereinafter, referred to as a “first element-containing gas”) is supplied to the shower head 230 from the first gas supply pipe 243a through the MFC 243c, the valve 243d, and a common gas supply pipe 242.

The first element-containing gas, which is one of the process gases, is a precursor gas (source gas). Here, the first element is, for example, silicon (Si). That is, the first element-containing gas is, for example, an Si-containing gas. A silane precursor gas is a silane precursor in a gaseous state, for example, a gas obtained by vaporizing a silane precursor in a liquid state under room temperature and normal pressure, a silane precursor in a gaseous state under room temperature and normal pressure, or the like. When the term “precursor” is used herein, it may refer to one of “a liquid precursor in a liquid state” or “a precursor gas in a gaseous state”, or both of them.

As the silane precursor gas, a precursor gas containing, for example, Si and a halogen element, i.e., a halosilane precursor gas, may be used.

The halosilane precursor gas is a halosilane precursor in a gaseous state, for example, a gas obtained by vaporizing a halosilane precursor in a liquid state under room temperature and normal pressure, a halosilane precursor in a gaseous state under room temperature and normal pressure, or the like. The halosilane precursor is a silane precursor having a halogen group. A halogen element includes at least one selected from the group consisting of chlorine (Cl), fluorine (F), bromine (Br), and iodine (I). That is, the halosilane precursor includes at least one halogen group selected from the group consisting of a chloro group, a fluoro group, a bromo group, and an iodine group. The halosilane precursor may be a sort of halogenide. When the term “precursor” is used herein, it may refer to one of “a liquid precursor in a liquid state,” or “a precursor gas in a gaseous state”, or both of them.

As the halosilane precursor gas, a precursor gas containing, for example, Si and Cl, i.e., a chlorosilane precursor gas, may be used. As the chlorosilane precursor gas, for example, a dichlorosilane (SiH₂Cl₂, abbreviation: DCS) gas, may be used. The DCS gas acts as an Si precursor (source) gas in a film forming process described later.

When the first element-containing gas uses a liquid precursor in a liquid state under room temperature and normal pressure, the precursor in a liquid state is vaporized by a vaporizing system such as a vaporizer or a bubbler, and supplied as a silane precursor gas. In this embodiment, a vaporizer may be installed between the first gas supply source 243b and the MFC 243c. In this embodiment, a gas will be described. Also, the silicon-containing gas acts as a precursor.

A downstream end of the first inert gas supply pipe 246a is connected to the first gas supply pipe 243a at a downstream side of the valve 243d. An inert gas supply source 246b, an MFC 246c, and a valve 246d are installed in the first inert gas supply pipe 246a in this order from the upstream direction.

In this embodiment, the inert gas is, for example, a nitrogen (N₂) gas. Also, as the inert gas, a rare gas such as, a helium (He) gas, a neon (Ne) gas, or an argon (Ar) gas, in addition to the N₂ gas, may be used.

An inert gas is supplied into the shower head 230 from the first inert gas supply pipe 246a through the MFC 246c, the valve 246d, and the first gas supply pipe 243a. The inert gas acts as a carrier gas or a dilution gas of the first element-containing gas in a thin film forming step S104 described later.

The first element-containing gas supply system 243 (also referred to as the first gas supply system, the precursor gas (source gas) supply system, the silicon-containing gas supply system, or the silane precursor gas supply system) is mainly configured by the first gas supply pipe 243a, the MFC 243c, and the valve 243d.

Further, a first inert gas supply system is mainly configured by the first inert gas supply pipe 246a, the MFC 246c, and the valve 246d. Also, it may be considered that the inert gas supply source 246b and the first gas supply pipe 243a are included in the first inert gas supply system.

In addition, it may be considered that the first gas supply source 243b and the first inert gas supply system are included in the first element-containing gas supply system.

### (Second Gas Supply System)

The remote plasma unit 244e is installed at a downstream side of the second gas supply pipe 244a. A second gas supply source 244b, an MFC 244c, and a valve 244d are installed at an upstream side the second gas supply pipe 244a in this order from the upstream direction.

A gas containing a second element (hereinafter, referred to as a “second element-containing gas”) is supplied into the shower head 230 from the second gas supply pipe 244a though the MFC 244c, the valve 244d, and the remote plasma unit 244e. The second element-containing gas turns into a plasma state by the remote plasma unit 244e and is supplied to the process chamber 201. In this manner, the second element-containing gas is supplied onto the wafer 200.

The second element-containing gas is one of the process gases. Also, the second element-containing gas may be considered as a reaction gas (reactant gas).

Here, the second element-containing gas contains a second element different from the first element, that is, a reactant having a different chemical structure from that of the precursor. As the second element, for example, a nitrogen (N)-containing gas, is supplied into the shower head 230 through the MFC 244c and the valve 244d.

The N-containing gas acts as a nitriding agent (nitriding gas), i.e., an N source, in a film forming process described later. As the N-containing gas, for example, an ammonia (NH₃) gas, a nitrogen (N₂) gas, or the like, may be used. When the NH₃ gas is used as the nitriding agent, for example, the gas is plasma-exited by using a plasma generating part described later and supplied as a plasma-excited gas (NH₃ gas).

The second element-containing gas supply system 244 (also referred to as the second gas supply system, the reaction gas (reactant gas) supply system, the nitrogen (N)-containing gas supply system, the nitriding agent supply system, or the nitriding gas supply system) is mainly configured by the second gas supply pipe 244a, the MFC 244c, and the valve 244d.

Further, a downstream end of the second inert gas supply pipe 247a is connected to the second gas supply pipe 244a at a downstream side of the valve 244d. An inert gas supply source 247b, an MFC 247c, and a valve 247d are installed in the second inert gas supply pipe 247a in this order from the upstream direction.

An inert gas is supplied into the shower head 230 from the second inert gas supply pipe 247a through the MFC 247c, the valve 247d, the second gas supply pipe 244a, and the remote plasma unit 244e. The inert gas acts as a carrier gas or a dilution gas of the second element-containing gas in a thin film forming step S104 described later.

A second inert gas supply system is mainly configured by the second inert gas supply pipe 247a, the MFC 247c, and the valve 247d. Also, it may be considered that the inert gas supply source 247b, the second gas supply pipe 243a, and the remote plasma unit 244e are included in the second inert gas supply system.

In addition, it may also be considered that the second gas supply source 244b, the remote plasma unit 244e, and the second inert gas supply system are included in the second element-containing gas supply system 244.

### (Third Gas Supply System)

A third gas supply source 245b, an MFC 245c, a valve 245d, a pipe heating part 245e as a gas heating part for heating a gas supplied from the third gas supply source mainly during the film forming step, and a gas heating device 253 positioned in an upstream side of the pipe heating part 245e and for heating a gas supplied from the third gas supply source mainly during an inner wall deposited film removing step are installed in the third gas supply pipe 245a in this order from the upstream direction.

As a heat source of the pipe heating part 245e, for example, a tape heater or a jacket heater wound around a pipe may be used. The heat source of the gas heating device 253 may be a heater having heating efficiency higher than that of the pipe heating part 245e, and for example, a lamp heater may be used.

Here, when the gas supplied from the third gas supply source 245b is heated by the pipe heating part 245e alone, the pipe heating part 245e is controlled by the controller 260 to reach a temperature ranging from 150 to 200 degrees C. (Celsius). When the gas supplied from the third gas supply source 245b is heated by the gas heating device 253 alone, the gas heating device 253 is controlled by the controller 260 to reach a temperature ranging from 500 to 1000 degrees C. (Celsius).

Further, since the gas heating device 253 is required to heat the gas supplied from the third gas supply source 245b described later to reach the above-described temperature, it is preferred to dispose the gas heating device 253 appropriately in the vicinity of the buffer chamber 232, that is, in a position close to the gas introduction port (hole 231a, etc.) installed in the lid 231. With this configuration, it is possible to suppress the lowering of the temperature of the third gas supplied from the third gas supply source 245b heated by the gas heating device. For example, when the gas heating device 253 is installed in a position spaced apart from the gas introduction port by reason of an installation space, maintenance, or the like, preferably, it is configured such that the pipe heating part 245e is installed between the gas introduction part 241 and the gas heating device 253, as illustrated in FIG. 1. By installing the pipe heating part 245e in this manner, it is possible to suppress the gas which is previously heated by the gas heating device 253 from being cooled due to heat release. That is, it is possible to keep the third gas supplied from the third gas supply source 245b which have been heated by the gas heating device at a desired temperature.

Further, in this embodiment, as illustrated in FIG. 1, both the pipe heating part 245e and the heating device 253 are installed, but only the heating device 253 may be installed to heat a gas supplied from the third gas supply source. In this case, the heating device 253 is disposed in a position close to the buffer chamber 232 such that the temperature of the purge gas heated by the heating device 253 is not lower than a desired temperature. More preferably, an insulating structure is installed between the O-ring 280 or the cooling medium supply valve 271 and the pipe 245a or the heating device 253 such that the O-ring 280 or the cooling medium supply valve 271 is not thermally affected.

In addition, when the supplied gas is heated using both the pipe heating part 245e and the gas heating device 253, a heating operation of each of the pipe heating part 245e and the gas heating device 253 may be independently controlled. By performing the controlling independently, since the temperature of the heated purge gas can be precisely controlled, it is possible to control the thermal influence on a peripheral structure such as the O-ring 280 or the cooling medium supply valve 271.

Also, it may be configured such that a metal having high heat resistance such as a nickel alloy is used in a part in gas contact with the gas supply pipe at a downstream side of the heating device 253 to thereby suppress the metal contamination due to a gas heated by the heating device 253 at a high temperature.

An inert gas as a purge gas is supplied to the shower head 230 from the third gas supply pipe 245a though the MFC 245c, the valve 245d, and the common gas supply pipe 245. The valve 245d may be installed at a position spaced apart from the gas heating device 253 so as not to be thermally affected by the gas heating device 253 or have an insulating structure, but a description thereof will be omitted for the convenience of description.

Here, the inert gas is, for example, a nitrogen (N₂) gas. Also, as the inert gas, a rare gas such as, a helium (He) gas, a neon (Ne) gas, or an argon (Ar) gas, in addition to the N₂ gas, may be used.

The purge gas heated by the pipe heating part 245e is supplied to the process chamber 201 through the buffer chamber 232 and the dispersion plate 234. In this manner, the dispersion plate 234 can be kept at a desired temperature.

For example, when the dispersion plate 234 is excessively cooled by supplying a purge gas which has not been heated, the following problems may arise. That is, since the gas remaining in the process chamber 201 has a temperature lower than a thermal decomposition temperature, byproducts may be deposited on a surface of the dispersion plate 234 facing the substrate, or the temperature of the process chamber 201 may not be maintained within a process window at a follow-up process gas supply step (for example, a first element-containing gas supply step after the second element-containing gas is supplied). As a result, the film processing characteristics of the follow-up step may be degraded.

Meanwhile, it is possible to suppress the above problems by heating the purge gas as in this embodiment.

A downstream end of a cleaning gas supply pipe 248a is connected to the third gas supply pipe 245a at a downstream side of the valve 245d. A cleaning gas supply source 248b, an MFC 248c, and a valve 248d are installed in the cleaning gas supply pipe 248a in this order from the upstream direction. The valve 245d may be installed at a position spaced apart from the gas heating device 253 so as not to be thermally affected by the gas heating device 253 or have an insulating structure, but a description thereof will be omitted for the convenience of description.

The third gas supply system 245 (also referred to as a third inert gas supply system) is mainly configured by the third gas supply pipe 245a, the MFC 245c, and the valve 245d.

Further, a cleaning gas supply system is mainly configured by the cleaning gas supply pipe 248a, the MFC 248c, and the valve 248d. Also, it may be considered that the cleaning gas supply source 248b and the third gas supply pipe 245a are included in the cleaning gas supply system.

In addition, it may be considered that the third gas supply source 245b and the cleaning gas supply system are included in the third gas supply system 245.

In the substrate processing process, an inert gas is supplied into the shower head 230 from the third gas supply pipe 245a through the MFC 245c and the valve 245d. Further, in the cleaning step, a cleaning gas is supplied into the shower head 230 through the MFC 248c and the valve 248d.

In the film forming step S104 described later, the inert gas supplied from the inert gas supply source 245b acts as a purge gas for purging the gas collected in the process chamber 202 or the shower head 230. Also, in the cleaning step, the inert gas may act as a carrier gas or a dilution gas of the cleaning gas.

In the cleaning step, the cleaning gas supplied from the cleaning gas supply source 248b acts as a cleaning gas for removing byproducts or the like attached to the shower head 230 or the interior of the process chamber 202.

Here, the cleaning gas is, for example, a nitrogen trifluoride (NF₃) gas. Also, as the cleaning gas, for example, a hydrogen fluoride (HF) gas, a chlorine trifluoride (ClF₃) gas, a fluorine (F₂) gas, or the like may be used, or any combination thereof may also be used.

### (Second Exhaust System)

An exhaust port 221 for exhausting atmosphere from the process chamber 201 is installed on an upper surface of an inner wall of the process chamber 201 (upper vessel 202a). An exhaust pipe 222 is connected to the exhaust port 221, and a pressure regulator 223, such as an APC, for controlling the interior of the process chamber 201 at a predetermined pressure, and a vacuum pump 224 are sequentially connected in series to the exhaust pipe 222. A second exhaust system (exhaust line) 220 is mainly configured by the exhaust port 221, the exhaust pipe 222, and the pressure regulator 223. Also, the vacuum pump 224 may be included in the second exhaust system 220.

### (Plasma Generating Part)

A matcher 251 and a high frequency power source 252 are connected to the lid 231 of the shower head. By adjusting impedance with the high frequency power source 252 and the matcher 251, plasma is generated in the buffer chamber 232 of the shower head 230 and the process chamber 201.

### (Controller)

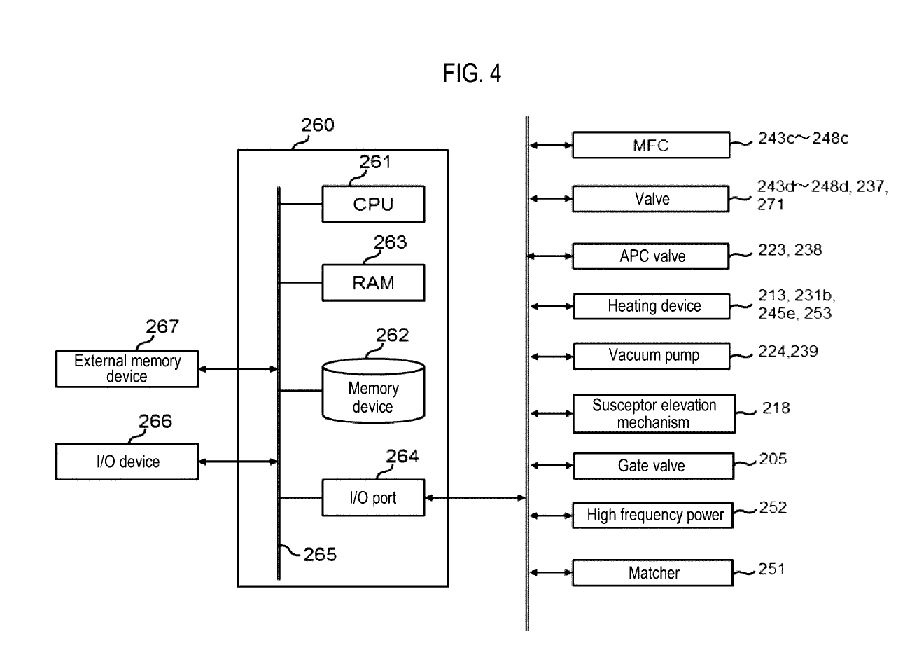

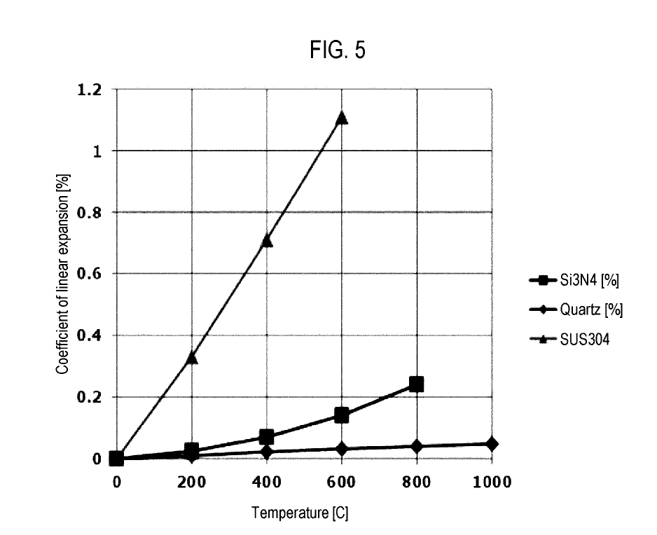

As illustrated in FIG. 4, the substrate processing apparatus 100 includes a controller 260 as a control part (control device) for controlling the operation of each part of the substrate processing apparatus 100. The controller 260 is configured as a computer having at least a central processing unit (CPU) 261 as an arithmetic part, a memory part 262, a random access memory (RAM) 263, and an I/O port 264. The memory part 262, the RAM 263, and the I/O port 264 are configured to exchange data with the CPU 261 via an internal bus 265. An input/output device 266 configured as, for example, a touch panel or the like, is connected to the controller 260.

The memory device 262 is configured with, for example, a flash memory, a hard disc drive (HDD), or the like. A control program for controlling the operation of the substrate processing apparatus, a process recipe in which a sequence, condition, or the like for substrate processing described later is written, and the like are readably stored in the memory device 262. In addition, the process recipe, which is a combination of sequences, causes the controller 260 to execute each sequence in a substrate processing process described later in order to obtain a predetermined result, and functions as a program. Hereinafter, the program recipe, the control program, or the like may be generally referred to simply as a program. Further, when the term “program” is used herein, it may include a case in which only the process recipe is included, a case in which only the control program is included, or a case in which both the process recipe and the control program are included. Further, the RAM 263 is configured as a memory area (work area) in which a program, data, or the like read by the CPU 261 is temporarily stored.

The I/O port 264 is connected to the MFCs 243c, 244c, 245c, 246c, 247c, and 248c, the valve 243d, 244d, 245d, 246d, 247d, 248d, and 237, the APC valves 223 and 238, the vacuum pumps 224 and 239, the heating devices 213, 231b, 245e, and 253, the matcher 251, the high frequency power source 252, the susceptor elevation mechanism 218, the gate valve 205, and the like, as described above.

The controller is connected to the MFCs 243c, 244c, 245c, 246c, 247c, and 248c, the valve 237, 243d, 244d, 245d, 246d, 247d, and 248d, the gate valve 205, the matcher 251, the high frequency power source 252, the APC valves 223 and 238, the vacuum pumps 224 and 239, and the susceptor elevation mechanism 218, and the like, as described above. The controller 260 is configured to invoke a program or a control recipe of the substrate processing apparatus from the memory part according to instructions from a higher controller or a user and control or perform the flow rate adjusting operation of various kinds of gases by the MFCs 243c, 244c, 245c, 246c, 247c, and 248c, the opening/closing operation of the valves 237, 243d, 244d, 245d, 246d, 247d, and 248d and the gate valve 205, the control of the matcher 251, the control of the high frequency power source 252, the opening/closing operation of the APC valves 223 and 238, the pressure regulation operation by the APC valves 223 and 238, the starting-up and stopping operation of the vacuum pumps 224 and 239, the elevation and lowering operation of the shaft 217 and support table 212 by the susceptor elevation mechanism 218, and the control of the pipe heating part 245e, the gas heating device 253, the cooling medium supply valve 271, etc.

In addition, the controller 260 may be configured by installing the above-described program stored in the external memory device 267 (for example, a magnetic tape, a magnetic disc such as a flexible disc or a hard disc, an optical disc such as a CD or DVD, a magneto-optical disc such as an MO, or a semiconductor memory such as a USB memory or a memory card) on the computer. The memory device 262 or the external memory device 267 is configured as a non-transitory computer-readable recording medium. Hereinafter, these will be generally referred to simply as a “recording medium”. When the term “recording medium” is used herein, it may include a case in which only the memory device 262 is included, a case in which only the external memory device 267 is included, or a case in which both the memory device 262 and the external memory device 267 are included. Further, the provision of the program to the computer may be performed using a communication means such as the Internet or a dedicated line, rather than through the external memory device 267.

### (2) Substrate Processing Process

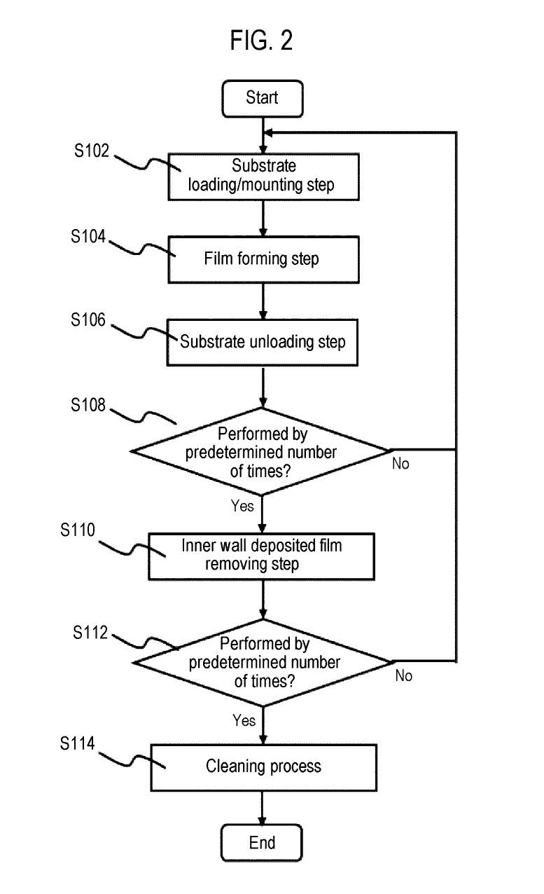

Next, a process of forming a thin film on the wafer 200 using the substrate processing apparatus 100 will be described with reference to FIGS. 2, 3, and 6. Also, in the following description, the operation of each of the parts that constitute the substrate processing apparatus 100 is controlled by the controller 260.

Here, an example in which a silicon nitride film (Si₃N₄ film, hereinafter, referred to as an SiN film), as a film containing Si and N, is formed on the wafer 200 by performing a step of supplying a DCS gas as a first element-containing gas and a step of supplying a plasma-excited NH₃ gas (NH₃* gas) as a second element-containing gas for a predetermined number of times (one or more times) non-simultaneously, that is, without synchronization, will be described. On the other hand, for example, a predetermined film may be formed on the wafer 200 in advance. Also, a predetermined pattern may be formed on the wafer 200 or on the predetermined film in advance.

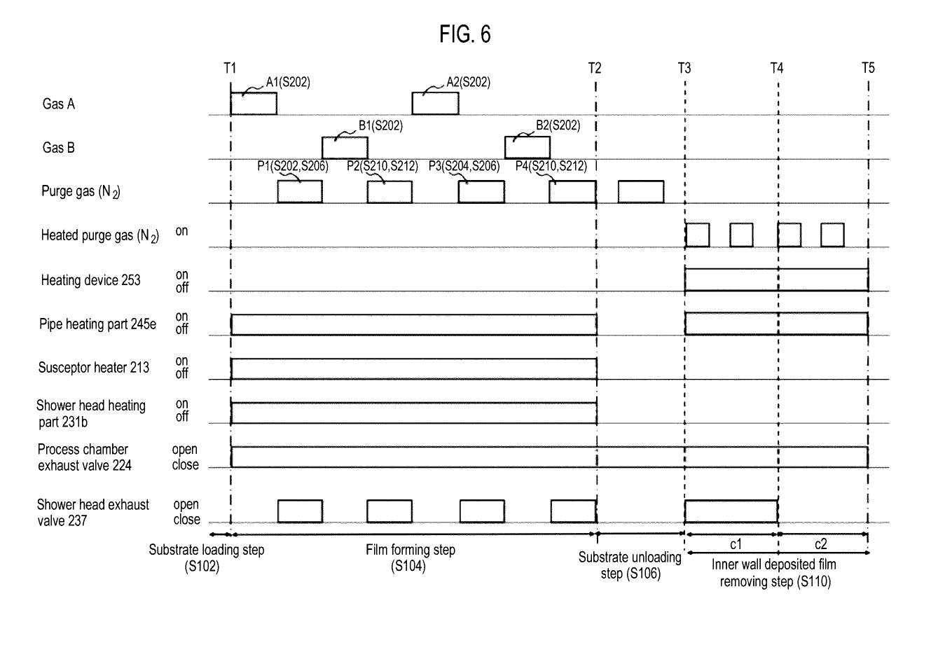

In the present disclosure, for the purposes of description, the sequence of film formation processing illustrated in FIG. 6 may be represented as follows for convenience sake. The same representation will also be used in the description of modifications or other embodiments described later.

(DCS'NH₃*)×n [symbol] SiN

In the present disclosure, the term “wafer” may mean not only a “wafer per se” but also a laminated body (aggregate) of a “wafer and certain layers or films formed on a surface of the wafer”, that is, a wafer including certain layers or films formed on a surface of the wafer is sometimes referred to as a wafer. Also, in the present disclosure, the term “surface of a wafer” may mean a “surface (exposed surface) of a wafer per se”, or a “surface of a certain layer or film formed on the wafer, namely an outermost surface of the wafer as a laminated body”.

Thus, in the present disclosure, the expression “supplying a specified gas to a wafer” may mean that the “specified gas is directly supplied to a surface (exposed surface) of a wafer per se”, or that the “specified gas is supplied to a layer or film formed on the wafer, namely to an outermost surface of the wafer as a laminated body”. Also, in the present disclosure, the expression “forming a certain layer (or film) on a wafer” may mean that the “certain layer (or film) is directly formed on the surface (exposed surface) of the wafer per se”, or that the “certain layer (or film) is formed on a layer or film formed on the wafer, namely on an outermost surface of the wafer as a laminated body”.

Also, in the present disclosure, the term “substrate” is interchangeably used with the term “wafer.”

### (Substrate Loading and Substrate Mounting Step S102)

In the processing apparatus 100, the substrate mounting table 212 is lowered to the transfer position of the wafer 200 to allow the lift pins 207 to pass through the through holes 214 of the substrate mounting table 212. As a result, the lift pins 207 are in a state where they protrude from the surface of the substrate mounting table 212 by a predetermined height. Subsequently, the gate valve 205 is opened to load the wafer 200 (substrate to be processed) into the process chamber and mount the same above the lift pins 207 using a wafer transfer device (not shown). Thus, the wafer 200 is supported in a horizontal position above the lift pins 207 that protrude from the surface of the substrate mounting table 212.

When the wafer 200 is loaded into the process vessel 202, the wafer transfer device is retreated to the outside of the process vessel 202, and the gate valve 205 is closed to make the inside of the process vessel 202 airtight. Thereafter, the wafer 200 is mounted on the substrate mounting surface 211 provided on the substrate mounting table 212 by elevating the substrate mounting table 212.

Further, when the wafer 200 is loaded into the process vessel 202, it is preferred that an N₂ gas as an inert gas is supplied into the process vessel 202 from the inert gas supply system, while exhausting the interior of the process vessel 202 by the exhaust system. That is, it is preferred that the N₂ gas is supplied into the process vessel 202 by opening the valve 245d of the third gas supply system in a state where the interior of the process vessel 202 is exhausted by operating the vacuum pump 224 to open the APC valve 223. Thus, it is possible to suppress the intrusion of particles into the process vessel 202 or the attachment of particles onto the wafer 200. Also, the vacuum p ump 224 is constantly operated until at least the substrate loading and mounting step S102 to a substrate unloading step S106 described later are completed.

When the wafer 200 is mounted on the substrate mounting table 212, it is controlled such that power is supplied to the heater 213 that is buried within the substrate mounting table 212 so that the surface of the wafer 200 has a predetermined temperature. At this time, the temperature of the heater 213 is adjusted by controlling a state of current applying to the heater 213 based on temperature information detected by a temperature sensor (not shown).

### (Film Forming Step S104).

Subsequently, a thin film forming step S104 will be described herein. A basic flow of the thin film forming step S104 will be described and details of the features of this embodiment will be described later.

In the thin film forming step S104, a DCS gas is supplied into the process chamber 201 through the buffer chamber 232 of the shower head 230. Thus, a Si-containing layer is formed on the wafer 200. When a predetermined period of time has elapsed since the DCS gas was supplied, the supply of the DCS gas is stopped and the DCS gas is discharged from the buffer chamber 232 and the process chamber 201 by a purge gas. When the purge gas is supplied to the process chamber 201, the process chamber 201 has been heated to a desired temperature by the pipe heating part 245e such that the dispersion plate 234 is not cooled and such that the temperature of the wafer 200 is increased.

After the DCS gas is discharged, an NH₃ gas activated by exciting plasma is supplied into the process chamber 201 through the buffer chamber 232. The NH₃ gas reacts with the Si-containing layer formed on the wafer 200 to form an SiN film. After a predetermined period of time, the supply of the NH₃ gas is stopped and an unheated purge gas is supplied into the process chamber 201 to discharge a residual NH₃ gas from the shower head 230 and the process chamber 201.

In the film forming step S104, the above process is repeatedly performed to form the SiN film having a desired film thickness. Also, during the film forming step, the shower head heating part 231b heats the buffer chamber 232 such that byproducts are not attached to the inner wall of the buffer chamber 232 as much as possible.

### (Substrate Unloading Step S106)

Subsequently, the substrate mounting table 212 is lowered to allow the wafer 200 to be supported above the lift pins 207 that protrude from the surface of the substrate mounting table 212. Thereafter, the gate valve 205 is opened to allow the wafer 200 to be unloaded to the outside of the process vessel 202 using the wafer transfer device. Thereafter, when the substrate processing process is completed, the supply of the inert gas into the process vessel 202 from the third gas supply system is stopped.

### (Processing Number Determining Step S108)

After the wafer 200 is unloaded, it is determined whether the thin film forming step has reached a predetermined number of times. When it is determined that the predetermined number of times is reached, the flow proceeds to an inner wall deposited film removing step. When it is determined that the predetermined number of times is not reached, the flow returns to the substrate loading and mounting step S102 in order to initiate a processing of a next wafer 200 which is waiting.

### (Inner Wall Deposited Film Removing Step S110).

In the film forming step S104, the buffer chamber 232 is heated such that byproducts are not be attached to the inner wall of the buffer chamber 232. However, byproducts are attached to the inner wall of the buffer chamber 232 according to a gas reservoir or an amount of a gas. In this step, a deposited film due to the byproducts attached to the buffer chamber 232 or the dispersion plate 234 during the film forming step S104 after the processing number determining step S108 is removed. Details of the removing step will be described later.

### (Processing Number Determination Step S112)

After the wafer 200 is unloaded, it is determined whether the inner wall deposited film removing step has reached a predetermined number of times. When it is determined that the predetermined number of times is reached, the flow proceeds to a cleaning step. When it is determined that the predetermined number of times is not reached, the flow returns to the substrate loading and mounting step S102 in order to initiate a processing of a next wafer 200 which is waiting.

### (Cleaning Step S114)

When it is determined in the processing number determining step S108 that the thin film forming step has reached a predetermined number of times, the cleaning step is performed on the interior of the shower head 230 and the process chamber 201. Here, the valve 248d of the cleaning gas supply system is opened and a cleaning gas is supplied to the process chamber 201 through the shower head 230.

When the shower head 230 and the process chamber 201 are filled with the cleaning gas, power is applied by the high frequency power source 252, impedance is matched by the matcher 251, and plasma of the cleaning gas is generated in the shower head 230 and the process chamber 201. The generated cleaning gas plasma removes byproducts attached on the shower head 230 and the inner wall of the process chamber 201.

Next, details of the film forming step S104 will be described with reference to FIG. 6.

### (First Process Gas Supply Step S202)

When the wafer 200 of the substrate mounting part 211 is heated to reach a desired first temperature, the valve 243d is opened and DCS as a first process gas starts to be supplied into the process chamber 201 through the gas introduction part 241, the buffer chamber 232, and the plurality of through holes 234a. Within the buffer chamber 232, the DCS gas is uniformly dispersed by the gas guide 235. The uniformly dispersed gas is uniformly supplied onto the wafer 200 within the process chamber 201 through the plurality of through holes 234a.

At this time, the MFC 243c is adjusted such that the DCS gas has a predetermined flow rate. Further, a supply flow rate of the DCS gas is adjusted to a value ranging from, for example, 1 sccm to 2000 sccm, preferably, 10 sccm to 1000 sccm. Also, an N₂ gas as a carrier gas may be flown from the first inert gas supply system, together with the DCS gas. In addition, a degree of the valve opening of the APC valve 223 is appropriately adjusted by operating the exhaust pump 224 to set an internal pressure of the process vessel 202 to a predetermined pressure. The internal pressure of the process chamber 201 ranges from, for example, 1 to 2666 Pa, preferably, 67 to 1333 Pa. A time duration in which the DCS gas is supplied to the wafer 200, that is, a gas supply time (radiation time), ranges from, for example, 0.01 to 60 seconds, preferably, 1 to 10 seconds.

By supplying the DCS gas to the wafer 200 under the above-described conditions, an Si-containing layer is formed on the wafer 200 (a base film on the surface of the wafer).

As a precursor, besides the DCS gas, a tetrakisdimethylaminosilane (Si[N(CH)₃)₂]₄, abbreviation: 4DMAS) gas, a trisdimethylaminosilane (Si[N(CH)₃)₂]₃H, abbreviation: 3DMAS) gas, a bisdimethylaminosilane (Si[N(CH₃)₂]₂H₂, abbreviation: BDMAS) gas, a bistert-butylaminosilane (SiH₂[NH(C₄H₉)]₂, abbreviation: BTBAS) gas, a bisdiethylaminosilane (Si[N(C₂H₅)₂]₂H₂, abbreviation: BDEAS) gas, and the like may be appropriately used. That is, as a precursor gas, various aminosilane precursor gases such as a dimethylaminosilane (DMAS) gas, a diethylaminosilane (DEAS) gas, a dipropylaminosilane (DPAS) gas, a diisopropylaminosilane (DIPAS) gas, a butylaminosilane (BAS) gas, and a hexamethyldisilazane (HMDS) gas, an inorganic halosilane precursor gas such as a monochlorosilane SiH₃Cl, abbreviation: MCS) gas, a dichlorosilane (SiH₂Cl₂, abbreviation: DCS) gas, a trichlorosilane (SiHCl₃, abbreviation: TCS) gas, a tetrachlorosilane, i.e., silicon tetrachloride (SiCl₄, abbreviation: STC) gas, a hexachlorodisilane (Si₂Cl₆, abbreviation: HCDS) gas, or an octachlorotrisilane (Si₃Cl₈, abbreviation: OCTS) gas, or an inorganic silane precursor gas, which does not contain a halogen group, such as a monosilane (SiH₄, abbreviation: MS) gas, a disilane (Si₂H₆, abbreviation: DS) gas, or a trisilane (Si₃H₈, abbreviation: TS) gas may be appropriately used.

After a predetermined period of time, the valve 243d is closed to stop the supply of the DCS gas.

### (First Shower Head Exhaust Step S204)

In a state where the supply of the DCS gas is stopped and the valve 244d is subsequently closed, the valve 247c is opened, the valve 245d is opened, and an internal atmosphere of the shower head 230 is exhausted. At this time, the vacuum pump 239 is operated in advance. An inert gas supplied from the second inert gas supply source 247b is supplied to the process chamber 201. In addition, an inert gas supplied from the third gas supply source 245b is heated to a predetermined temperature by the heater 245e and supplied to the shower head 230 and the process chamber 201. The substrate 200 is heated to reach a reaction acceleration temperature of an NH₃ gas activated by exciting plasma as the second element-containing gas, by the supplied inert gas. The impurities included in the first element-containing gas may be easily eliminated in the first element-containing layer formed on the surface of the heated substrate 200.

At this time, an opening/closing valve of the valve 237 and the vacuum pump 239 are controlled such that exhaust conductance (displacement) from the first exhaust system in the buffer chamber 232 is higher than that from the second exhaust system through the process chamber 201. Through this adjustment, a gas flow from the center of the buffer chamber 232 toward the shower head exhaust hole 236a is formed. In this manner, a gas attached to the wall of the buffer chamber 232 or a gas floating in the buffer space is exhausted from the first exhaust system, without entering the process chamber 201.

Further, a gas remaining in the buffer chamber 232 may not completely be excluded and the interior of the buffer chamber 232 may not completely be purged. When the amount of the gas remaining in the buffer chamber 232 is very small, it may not adversely affect the subsequent purging process. At this time, a flow rate of the N₂ gas supplied into the buffer chamber 232, and need not be high. For example, the approximately same amount of the N₂ gas as the volume of the buffer chamber 232 may be supplied, so that the purging may be performed without adversely affecting the purging process. As described above, since the interior of the buffer chamber 232 is not completely purged, the purge time can be reduced which in turn can improve the throughput. In addition, the consumption of the N₂ gas can also be restricted to a required minimal amount.

### (First Process Chamber Exhaust Step S206)

After a predetermined period of time, a degree of the valve opening of the APC valve 223 and a degree of the valve opening of the valve 237 are adjusted such that the exhaust conductance from the second exhaust system is higher than that from the first exhaust system through the shower head 230 in the process space, while continuously operating the exhaust pump 224 of the second exhaust system. Through this adjustment, a gas flow toward the second exhaust system by way of the process chamber 201 is formed. Thus, the inert gas supplied to the buffer chamber 232 can be surely supplied onto the substrate, increasing the efficiency of removing a residual gas on the substrate. Also, at this time, the inert gas is heated to exhaust the interior of the first process chamber.

At this time, the gas remaining in the process chamber 201 may not be completely excluded and the interior of the process chamber 201 may not be completely purged. When the amount of the gas remaining in the process chamber 201 is very small, it may not adversely affect the subsequent purging process. At this time, a flow rate of the N₂ gas supplied into the process chamber 201 also need not be high. For example, the approximately same amount of the N₂ gas as the volume of the process chamber 201 may be supplied, so that the purging may be performed without adversely affecting the purging process. As described above, since the interior of the process chamber 201 is not completely purged, the purge time can be reduced which in turn can improve the throughput. In addition, the consumption of the N₂ gas can also be restricted to a required minimal amount.

The inert gas supplied in the process chamber exhaust step removes from the wafer 200 the DCS gas, which does not react or has contributed to the formation of the Si-containing layer, which remains in the process chamber 201. In addition, the valve 237 is opened and the pressure regulator 237 and the vacuum pump 238 are controlled to remove the DCS gas remaining in the shower head 230. After a predetermined period of time, the valve 243d is closed to stop the supply of the inert gas, and the valve 237 is closed to block between the shower head 203 and the vacuum pump 239.

Preferably, after a predetermined period of time, the valve 237 is closed, while continuously operating the exhaust pump 224 of the second exhaust system. In this manner, since the flow toward the second exhaust system by way of the process chamber 201 is not affected by the first exhaust system, the inert gas can be more surely supplied onto the substrate, thereby further increasing the efficiency of removing the residual gas on the substrate.

Further, by performing the first process chamber exhaust step S206 continuously after the first shower head exhaust step S204, the following effects can be obtained. That is, since the residue in the buffer chamber 232 is removed in the shower head exhaust step S204, even though the gas flow goes through the surface of the wafer 200 in the process chamber exhaust step S206, the residual gas can be prevented from being attached onto the substrate.

### (Second Process Gas Supply Step S208)

After the first process chamber exhaust step, the valve 244d is opened, and thus, a nitrogen-containing gas as an active species activated (excited) by plasma by the remote plasma unit 244e is supplied into the process chamber 201 through the gas introduction part 241, the buffer chamber 232, and the plurality of through holes 234a. Since the nitrogen-containing gas is supplied to the process chamber 201 through the buffer chamber 232 and the through holes 234a, an NH₃ gas activated (excited) by plasma can be uniformly supplied onto the substrate. Thus, a film thickness can be uniform.

At this time, the MFC 244c is adjusted such that the plasma-excited NH₃ gas has a predetermined flow rate. Further, a supply flow rate of the NH₃ gas is a flow rate ranging from, for example, 100 sccm to 10000 sccm. A high frequency power applied to the shower head 230 also serving as an electrode ranges from, for example, 50 to 1000 W. An internal pressure of the process chamber 201 ranges from, for example, 1 to 100 Pa. A time duration in which the active specifies obtained by plasma-exciting the NH₃ gas are supplied to the wafer 200, i.e., a gas supply time (irradiation time) ranges from, for example, 1 to 100 seconds, preferably, 1 to 50 seconds. Other processing conditions are the same as those of the above-described step S202. Also, an N₂ gas as a carrier gas may be flown from the second inert gas supply system, together with the NH₃ gas.

For the ions produced in the nitrogen plasma and the electrically neutral active specifies, nitriding described later is performed on the Si-containing layer formed on the surface of the wafer 200.

By supplying the NH₃ gas to the wafer 200 under the above-described conditions, the Si-containing layer formed on the wafer 200 is plasma-nitrided. At this time, an Si-halogen bond and an Si—H bond of the Si-containing layer are broken due to the energy of the plasma-excited NH₃ gas. The halogen group and H separated from the bond with Si are eliminated from the Si-containing layer. Further, Si of the Si-containing layer having a dangling bond as the H, or the like, which is eliminated, is combined with N contained in the NH₃ gas to form an Si—N bond. As this reaction is in progress, the Si-containing layer is changed (modified) to a layer containing Si and N, i.e., a silicon nitride layer (SiN layer).

Further, in order to modify the Si-containing layer to the SiN layer, the NH₃ gas needs to be plasma-excited and supplied. This is because, even though the NH₃ gas is supplied under a non-plasma atmosphere, the energy required for nitriding the Si-containing layer is insufficient in the above-described temperature zone, making it difficult to increase the Si—N bond by sufficiently eliminating H or halogen from the Si-containing layer or sufficiently nitriding the Si-containing layer.

After a predetermined period of time, the valve 244d is closed to stop the supply of the NH₃ gas.

As a nitriding agent, i.e., as an N-containing gas for exciting plasma, a hydronitrogen-based gas such as an ammonia (NH₃) gas, a diagen (N₂H₂) gas, a hydrazine (N₂H₄) gas, or an N₃H₈ gas, or a gas containing these compounds, or the like may be used. Further, as a reaction gas, an ethylamine-based gas such as a triethylamine ((C₂H₅)₃N, abbreviation: TEA) gas, a diethylamine ((C₂H₅)₂NH, abbreviation: DEA) gas, or a monoethylamine (C₂H₅NH₂, abbreviation: MEA) gas, or a methylamine-based gas such as a trimethylamine ((CH₃)₃N, abbreviation: TMA) gas, a dimethylamine ((CH₃)₂NH, abbreviation: DMA) gas, or a monomethylamine (CH₃NH₂, abbreviation: MMA) gas, or the like may be used. Also, as a reaction gas, an organic hydrazine-based gas such as a trimethylhydrazine ((CH₃)₂N₂(CH₃)H, abbreviation: TMH) gas, or the like is used, and even when an SiN film is formed on the wafer through the film formation sequence, the present disclosure can be appropriately applied.

### (Second Shower Head Exhaust Step S210)

After the supply of the NH₃ gas is stopped, the valve 237 is opened to exhaust the internal atmosphere of the shower head 230. Specifically, the internal atmosphere of the buffer chamber 232 is exhausted. At this time, a heated purge gas is supplied from the third gas supply system 245 to exhaust the internal atmosphere of the buffer chamber 232, while maintaining the temperature of the dispersion plate 234. The second shower head exhaust step S210 will be described in detail later.

An opening/closing valve of the valve 237 and the vacuum pump 239 are controlled such that exhaust conductance (displacement) from the first exhaust system in the buffer chamber 232 is higher than that from the second exhaust system through the process chamber 201. Through this adjustment, a gas flow from the center of the buffer space 232 toward the shower head exhaust hole 236a is formed. In this manner, a gas attached to the wall of the buffer chamber 232 or a gas floating in the buffer space is exhausted from the first exhaust system, without entering the process chamber 201.

### (Second Process Chamber Exhaust Step S212)

After a predetermined period of time, a degree of the valve opening of the APC valve 223 and a degree of the valve opening of the valve 237 are adjusted such that the exhaust conductance from the second exhaust system is higher than that from the first exhaust system through the shower head 230 in the process space, while continuously operating the exhaust pump 224 of the second exhaust system. Through this adjustment, a gas flow toward the second exhaust system by way of the process chamber 201 is formed. Thus, the inert gas supplied to the buffer chamber 232 can be surely supplied onto the substrate, thereby increasing the efficiency of removing a residual gas on the substrate.

An inert gas supplied in the second process chamber exhaust step S212 removes from the wafer 200 an NH₃ gas component which was not combined to the wafer 200 in the second process gas supply step S208. Specifically, the valve 237 is opened and the pressure regulator 238 and the vacuum pump 239a are controlled to remove the nitrogen gas remaining in the buffer chamber 232 and the process chamber 201. After a predetermined period of time, the valve 243d is closed to stop the supply of the inert gas, and simultaneously the valve 237 is closed to block between the shower head 203 and the vacuum pump 239.

Preferably, after a predetermined period of time, the valve 237 is closed, while continuously operating the exhaust pump 224 of the second exhaust system. In this manner, since the residual gas in the buffer chamber 232 or the supplied inert gas may not be affected by the second exhaust system, the inert gas can be more surely supplied onto the substrate, further increasing the efficiency of removing the residual gas which has not entirely reacted with the first process gas on the substrate.

Further, by performing the process chamber exhaust step S212 continuously after the shower head exhaust step S210, the following effects can be obtained. That is, since the residue in the buffer chamber 232 is removed in the shower head exhaust step S210, even though a gas flow passes through the wafer 200 in the process chamber exhaust step S212, the residual gas can be prevented from being attached onto the substrate.

### (Determination S214)

The controller 260 determines whether steps S202 to S212 described above are set to 1 cycle and performed a predetermined number of times.

When the predetermined number of times is not performed (“NO” in step S214), the cycle of the first process gas supply step S202, the first shower head exhaust step S204, the first process chamber exhaust step S206, the second process gas supply step S208, the second shower head exhaust step S210, and the second process chamber exhaust step S212 is repeated. When the predetermined number of times is performed (“YES” in step S214), the film forming step S104 is terminated.

Next, details of the inner wall deposited film removing step S110 illustrated in FIGS. 2 and 6 will be described.

FIG. 6 illustrates a state where a gas A (DCS gas as a first process gas), a gas B (NH₃ gas as a second process gas), a purge gas (N₂ gas as an inert gas), a heated purge gas (N₂ gas as an inert gas heated by the heating device 253) are supplied to the process chamber 201 in the film forming step S104, the substrate unloading step S106, and the deposited film removing step S110, a heating state of the pipe heating part 245e of the third gas supply system 245, a heating state of the heating device 253, a heating state of the substrate mounting part heater 213, a heating state of the shower head heating part 231b, a state of a degree of the valve opening of the APC valve 223 of the second exhaust system 220, and an opening/closing state of the valve 237 of the first exhaust system 240.

In the example of FIG. 6, in the film forming step S104 from a time T1 to a time T2, a gas A supply step A1, a gas A exhaust step P1 (the first shower head exhaust step S204 and the first process chamber exhaust step S206), a gas B supply step B1, a gas B exhaust step P2 (the second shower head exhaust step S210 and the second process chamber exhaust step S212), a gas A supply process A2, a gas A exhaust step P3, a gas B supply step B2, and a gas B exhaust step P4 are sequentially performed. Further, an inert gas such as N₂ may be contained as a carrier gas in A1, A2, B1, and B2. Also, in FIG. 6, the purge gas supply steps P1 to P4 are illustrated as being discontinuous, but they may be continuous.

As illustrated in FIG. 6, in the film forming step S104, the pipe heating part 245e of the third gas supply system 245, the substrate mounting part heater 213, and the shower head heating part 231b are all turned on, that is, heated. Further, a degree of the valve opening of the APC valve 223 of the second exhaust system 220 is constantly in an open state, that is, exhausting is constantly performed by the second exhaust system 220. Also, the valve 237 of the first exhaust system is open during the periods of P1, P2, P3, and P4 in which a purge gas is supplied. Also, as described above, in each of the P1, P2, P3, and P4, the valve 237 may be closed in the first process chamber exhaust step S206 and the second process chamber exhaust step S212 to stop the exhausting from the first exhaust system.

Thereafter, in the substrate unloading step S106 from the time T2 to a time T3, the processed wafer 200 is unloaded from the process chamber 201. In the substrate unloading step S106, the exhausting from the second exhaust system 220 is performed, but the exhausting from the first exhaust system 240 is stopped. Further, a purge gas is supplied from the third gas supply system 245 to the process chamber 201. Also, the pipe heating part 245e of the third gas supply system 245, the substrate mounting part heater 213, and the shower head heating part 231b are all in an OFF state, that is, stopped.

Subsequently, in the deposited film removing step S110 from the time T3 to a time T5, a deposited film attached to the inner wall of the buffer chamber 232 or the dispersion plate 234 is removed. Specifically, a first step c1 of the deposited film removing step S110 is performed from the time T3 to a time T4, and a second step c2 of the deposited film removing step S110 is performed from the time T4 to the time T5.

For example, an internal pressure of the process chamber 201 in the first step c1 ranges from about 2050 to 2100 Pa, and pressure within the buffer chamber 232 is about 2000 Pa. Further, an internal pressure of the process chamber 201 in the second step c2 is about 500 Pa, and an internal pressure of the buffer chamber 232 is about 2000 Pa. In this manner, in the first step c1, the internal pressure of the process chamber 201 is higher than that of the buffer chamber 232, and in the second step c2, the internal pressure of the buffer chamber 232 is higher than that of the process chamber 201.

In the deposited film removing step S110, exhausting is performed from the first exhaust system 240 and the second exhausting system 220. Further, a purge gas from the third gas supply system 245 is supplied into the buffer chamber 232 or the process chamber 201. Also, the substrate mounting part heater 213 and the shower head heating part 231b are all in an OFF state. Also, heating of the pipe heating part 245e of the third gas supply system 245 and the heating device 253 are all in an ON state.

In the first step c1, both the pipe heating part 245e of the third gas supply system 245 and the heating device 253 are turned on and the purge gas from the third gas supply system 245 is heated (hereinafter, the purge gas from the third gas supply system 245 heated by the heating device 253 will be referred to as a heated purge gas). That is, the temperature of the heated purge gas in the deposited film removing step S110 is set to be higher than that of the purge gas in the film forming step S104. For example, the temperature of the heated purge gas in the deposited film removing step S110 ranges from 300 to 1000 degrees C. (preferably, from 500 to 800 degrees C.), and the temperature of the purge gas in the film forming step S104 ranges from 150 to 200 degrees C. (preferably, from 160 to 180 degrees C.). At this time, as described above, the shower head heating part 231b is turned off, so that the inner wall of the buffer chamber 232 or the dispersion plate 234 is not heated. Since the shower head heating part 231b is turned off, a temperature difference described later can be remarkable. Here, it is preferred that a difference between the temperature of the heated purge gas and the temperature of the interior of the buffer chamber or the process chamber is controlled to have a range of 50 to 200 degrees C.

When controlled in this manner, thermal stress is generated by a temperature gradient caused due to a difference between the temperature of the deposited film heated by the heated purge gas supplied into the buffer chamber 232 and the temperature of the inner wall of the buffer chamber 232 or the dispersion plate 234, causing a crack in the deposited film attached to the inner wall of the buffer chamber 232 or the surface of the dispersion plate 234 to facilitate film delamination.

For example, when the lid 231 of the shower head is formed of stainless steel (SUS304) and a deposited film deposited on an inner surface of the lid is an SiN film, it is possible to heat the SiN film before the lid 231 of the shower head formed of stainless steel having high thermal conductivity is heated by directly jetting the heated purge gas to the deposited film. That is, only the SiN film can be heated to cause a temperature gradient between the lid 231 and the SiN film. Thus, it is easy to cause a crack in the SiN film to facilitate film delamination.

Thus, the deposited film can be easily removed.

Further, in this embodiment, as illustrated in FIG. 6, when there is a difference in a coefficient of linear expansion between the inner wall of the buffer chamber 232 or the dispersion plate 234 or the inner wall of the process chamber or the like, and the deposited film, like the stainless steel and the SiN film, the deposited film can be effectively removed. However, the present disclosure is not limited thereto and even when there is little difference in the coefficient of linear expansion between the inner wall of the buffer chamber or the dispersion plate 234 or the inner wall of the process chamber or the like, and the deposited film, such as a case in which the deposited film is an SiN film and a base member of the deposited film is quartz (SiO₂) or in a case in which the deposited film is an SiO₂ film and a base member of the deposited film is quartz, it is easy to cause a crack in the deposited film to facilitate film delamination. This is because only the deposited film is directly heated by the heated purge gas to cause a temperature gradient between the deposited film and the base member. Thus, the deposited film can be easily removed effectively, regardless of the difference in the coefficient of linear expansion between the base member and the deposited film.

Here, for example, as illustrated in FIG. 6, it is preferred that the supply of the heated purge gas is intermittently performed. By intermittently supplying the heated purge gas, a reduction in thermal stress results from a decrease in the temperature difference between the temperature of the supplied heated purge gas and the internal temperature of the substrate processing apparatus 100, specifically the internal temperature of the shower head, more specifically the temperature of the buffer chamber 232 or the dispersion plate 234 when the internal temperature increases, that is, the difficulty of a film being delaminated is suppressed. For example, when the purge gas is continuously supplied, since the inner wall of the heat processing apparatus 100 or the deposited film, or the like is continuously heated to have a high temperature, a difference between the temperature of the substrate processing apparatus 100 and the temperature of the purge gas is reduced, as described above.

In addition, by intermittently supplying the heated purge gas having a high temperature as described above, it is possible to reduce a thermal load to the substrate processing apparatus 100, in particular, a peripheral component of the process chamber.

Further, in the first step c1, the shower head exhaust valve 237 and the APC valve 223 as the process chamber exhaust valve are opened to perform exhausting from the first exhaust system 240 and the second exhaust system 220. At this time, the APC valve 237 of the second exhaust system 240 or the APC valve 223 of the first exhaust system 220 is controlled such that a flow rate (exhaust flow rate) of a purge gas exhausted by the first exhaust system 240 is greater than that of a purge gas exhausted by the second exhaust system 220.

By performing the controlling in this manner, the film delaminated from the inner wall of the buffer chamber 232 or the dispersion plate 234 is suppressed from being supplied into the through hole 234a of the dispersion plate 234. Thus, the through hole 234a is suppressed from being stopped by the delaminated film. Also, it is easy to delaminate the deposited film covering the interior of the through hole 234a of the dispersion plate 234 and discharge the delaminated deposited film from the first exhaust system 240. Also, through the exhausting from the second exhaust system 220, the delaminated film or particles from the inner wall of the process chamber 201 is discharged from the interior of the process chamber 201. In this manner, the film delaminated from the inner wall of the buffer chamber 232 or the dispersion plate 234 is suppressed from being supplied into the through hole 234a of the dispersion plate 234. Thus, the through hole 234a is suppressed from being stopped by the delaminated film. Also, it is easy to delaminate the deposited film covering the interior of the through hole 234a of the dispersion plate 234 and discharge the same from the first exhaust system 240. Also, through exhausting from the second exhaust system 2200, the delaminated film or particles from the inner wall of the process chamber 201 is discharged from the interior of the process chamber 201.

Preferably, the APC valve 273 of the first exhaust system 240 or the APC valve 223 of the second exhaust system 220 is controlled such that the conductance of the first exhaust system 240 within the buffer chamber 232 is greater than that of the second exhaust system 220 through the process chamber 201. In this manner, the internal atmosphere of the buffer chamber 232 does not flow into the process chamber 201, and the internal atmosphere of the process chamber 201 flows into the buffer chamber 232.

In this manner, the film delaminated from the inner wall of the buffer chamber 232 or the dispersion plate 234 is discharged from the first exhaust system 240. Also, after a predetermined period of time in which most of films delaminated from the inner wall of the buffer chamber 232 or the dispersion plate 234 is discharged from the first exhaust system 240, when the shower head exhaust valve 237 is closed, the first step c1 is terminated and the second step c2 is started.

Also, in the first step c1, it may be configured such that the exhausting from the second exhaust system 220 is stopped. Also in this manner, even though the delaminated film or particles from the inner wall of the process chamber 201 may not be discharged from the interior of the process chamber 201, but the film delaminated from the inner wall of the buffer chamber 232 or the dispersion plate 234 can be discharged from the first exhaust system 240.

In the second step c2, since exhausting from the first exhaust system 240 is stopped, the heated purge gas from the third gas supply system 245 flows from the buffer chamber 232 toward the process chamber 201.

Since the heated purge gas from the third gas supply system 245 passes through the through hole 234a of the dispersion plate 234, the heated purge gas delaminates an extraneous matter within the through hole 234a and extrudes the same from the through hole 234a. The extruded extraneous matter is discharged from the second exhaust system 220.

Further, as described above, in the second step c2, it is preferred that the substrate mounting part heater (susceptor heater) 213 is turned off. By turning off the susceptor heater 213, the dispersion plate 234 is heat-released to have a low temperature. Thus, a difference in temperature between the dispersion plate 234 and the purge gas, that is, a difference in temperature between the deposited film attached to the dispersion plate 234 and the purge gas, is further increased. That is, the thermal stress of the deposited film is further increased. Thus, it is more easy to delaminate the deposited film attached to the dispersion plate 234.

Further, in any one of the first step c1 and the second step c2, or in both of them, it is preferred that the flow rate of the heated purge gas from the third gas supply system 245 is controlled by the mass flow controller 245c such that the flow rate of the heated purge gas is greater than that of the purge gas in the film forming step S104.

In this manner, the heated purge gas having a flow rate greater than that in the film forming step S104 collides with the inner wall of the buffer chamber 232 or the dispersion plate 234, further facilitating delamination of the deposited film attached to the inner wall of the buffer chamber 232 or the dispersion plate 234.

Further, it is preferred that the cooling medium supply valve 271 may be opened to allow a refrigerant to be flown to the cooling channel 270, between the first step c1 and the second step c2. By allowing the refrigerant to be flown, even though the heated purge gas is supplied, the dissolution of the O-ring can be suppressed.

Further, in any one of the first step c1 and the second step c2, or in both of them, it may be configured such that the susceptor heater 213 or the shower head heating part 231b are turned on. Also, in this manner, since the temperature of the heated purge gas is higher than that of the purge gas in the film forming step S104, the film attached to the inner wall of the buffer chamber 232 or the dispersion plate 234 can be somewhat delaminated.

### (3) Effects of the Present Embodiment

According to the present disclosure, one or more effects are provided as described below.

(A1) Since it is configured such that the purge gas (inert gas) having a temperature higher than that of the purge gas (inert gas) supplied in the film forming step is directly supplied into the shower head in the deposited film removing step, it is possible to directly heat only a deposited film deposited on the member such as the gas guide installed within the shower head, applying great thermal stress to the deposited film within the shower head, compared with a case of heating or cooling from the outside. That is, it is easy to remove the deposited film from the interior of the shower head.

(A2) Since it is configured such that the purge gas (inert gas) having a temperature higher than that of the purge gas (inert gas) supplied in the film forming step is supplied into the process chamber in the deposited film removing step, it is possible to directly heat only a deposited film deposited on the member within the process chamber such as the partition plate 204 exposed within the process chamber, applying great thermal stress to the deposited film within the process chamber, compared with the case of heating or cooling from the outside. That is, it is easy to remove the deposited film from the interior of the process chamber.

(A3) Since it is configured such that the deposited film is directly heated in the deposited film removing step by supplying the purge gas (inert gas) having a temperature higher than that of the purge gas (inert gas) supplied in the film forming step, even though there is no difference in coefficient of linear expansion between the base member and the deposited film, it is possible to effectively remove the deposited film.

(A4) By directly supplying the heated purge gas heated to have a temperature ranging from 300 to 1000 degrees C. into the buffer chamber 232 of the shower head 230 and the process chamber 201 in the deposited film removing step, it is possible to increase a temperature gradient between the deposited film and the member installed in the buffer chamber or the process chamber, easily causing a crack in the deposited film to facilitate removing of the deposited film from the interior of the shower head and the process chamber.

(A5) By alternately supplying the heated purge gas heated to have a temperature ranging from 300 to 1000 degrees C. and the unheated purge gas (inert gas) having a general temperature directly into the buffer chamber 232 and the process chamber 201 in the deposited film removing step, it is possible to increase a temperature gradient generated in the deposited film, facilitating the generation of a crack in the deposited film to easily remove the deposited film from the interior of the shower head and the interior of the process chamber.

(A6) By intermittently supplying the heated purge gas heated to have a temperature ranging from 300 to 1000 degrees C. into the buffer chamber 232 of the shower head 230 and the process chamber 201 in the deposited film removing step, it is possible to reduce a thermal load to the substrate processing apparatus 100, in particular, to a component within the process chamber.

### (4) Modifications

The substrate processing process in this embodiment is not limited to the above-described aspects and may be modified as in modifications described below.

### (Modification 1)

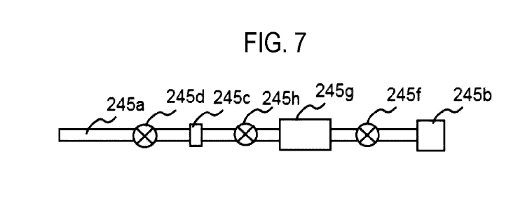

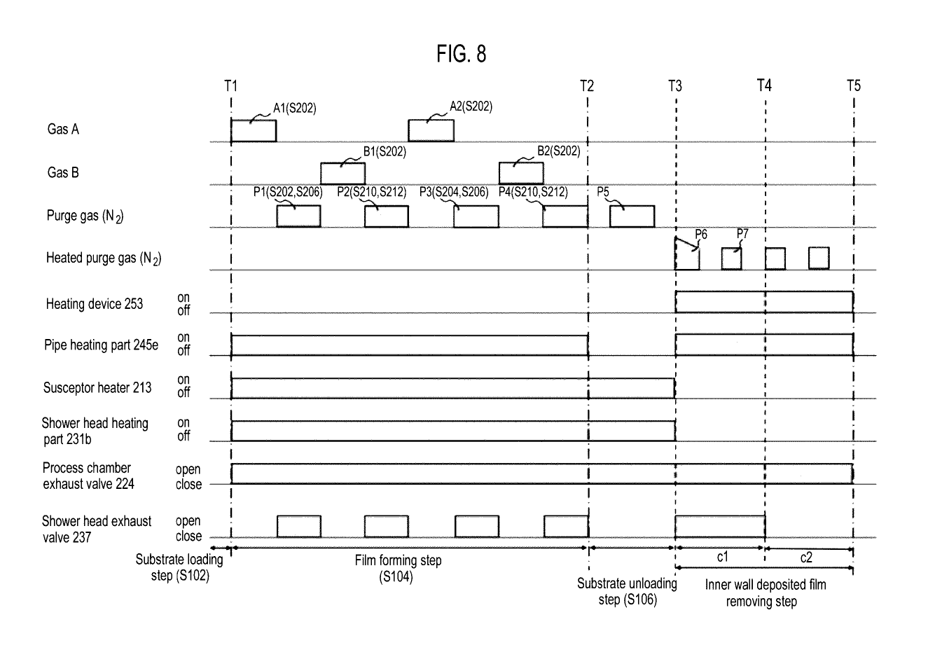

Next, modification 1 of the present disclosure will be described with reference to FIGS. 7 and 8. Only a third gas supply system and a controller for controlling the third gas supply system illustrated in FIG. 7 in a substrate processing apparatus of modification 1 are different from those of the substrate processing apparatus of the first embodiment, and other components thereof are the same as those of the first embodiment.

Specifically, as illustrated in FIG. 7, in the third gas supply system 245, a valve 245f as an opening/closing valve, a tank 245g as a gas storage part for storing a gas, and a valve 245h as an opening/closing valve are additionally configured between the third gas supply source 245b and an WC 245c.

An operation of the third gas supply system of modification 1 will be described with reference to FIG. 8. As described above, a flow rate of a heated purge gas from the time T3 to the time T4 and a method for allowing the heated purge gas to be flown in FIG. 8 are different from those of FIG. 6 of the first embodiment, and other conditions of FIG. 8 are the same as those of FIG. 6.

As illustrated in P6 of FIG. 8, in modification 1, the heated purge gas from the third gas supply system 245 in the first step c1 of the deposited film removing step S110 is supplied into the buffer chamber 232 or the process chamber 201. At this time, at the time T3, the heated purge gas stored in the tank 245g of the third gas supply system 245 is supplied into the buffer chamber 232 at a time as the valve 245d and the valve 245h are opened. The capacity of the tank 245g is set such that an initial flow rate (flow rate at the time of initiating supply) of the purge gas supplied into the buffer chamber 232 is greater than that of the heated purge gas in the first embodiment.

As illustrated in P6 of FIG. 8, the flow rate of the heated purge gas supplied into the buffer chamber 232, which is great when it is started to be supplied, is gradually reduced to be resultantly equal to that of the heated purge gas supplied into the buffer chamber 232 in the first embodiment. Also, the shape of P6 of FIG. 8 roughly indicates the flow rate, rather than being accurate.

In this manner, since the initial flow rate of the purge gas supplied to the shower head is greater than the flow rate when the supply of the purge gas is terminated, it is easy to increase the flow rate of the purge gas supplied to the shower head. Further, since the pressure of the purge gas colliding with the inner wall of the buffer chamber 232 or the dispersion plate 234 is changed within a short time and it is also possible to heat the inner wall of the buffer chamber 232 or the dispersion plate 234 to have a high temperature within a short time, the deposited film attached to the inner wall of the buffer chamber 232 or the dispersion plate 234 can be more easily delaminated.

In addition, storing of the heated purge gas in the tank 245g is performed by opening the valve 245f with the valve 245d and the valve 245h closed, after the termination of P5 from the time T2 to the time T3. Thereafter, after a predetermined amount of the heated purge gas is stored in the tank 245g, as described above, the valve 245d and the valve 245h are opened at the timing of T3 of FIG. 7, so that the heated purge gas is supplied from the tank 245g into the buffer chamber 232 at a time.

An operation of the third gas supply system in the second step c2 of modification 1 is the same as that of the third gas supply system in the second step c2 of the first embodiment. Also, since the operation of the third gas supply system in the film forming step S104 of modification 1 is performed in a state where the valve 245f and the valve 245h are constantly opened, it is the same as the operation of the third gas supply system in the film forming step S104 of the first embodiment.

With the configuration as in modification 1, at least one of the following effects is provided.

(B1) Since the flow rate of the heated purge gas (inert gas) supplied to the shower head in the deposited film removing step is configured to be greater than that of the heated purge gas (inert gas) supplied to the shower head in the film forming step, it is easy to remove the deposited film from the interior of the heated shower head.

(B2) Since the flow rate the heated purge gas (inert gas) supplied to the shower head when it is started to be supplied in the deposited film removing step is configured to be greater than that when the supply of the purge gas is terminated, it is easy to remove the deposited film from the interior of the shower head.

### (Modification 2)

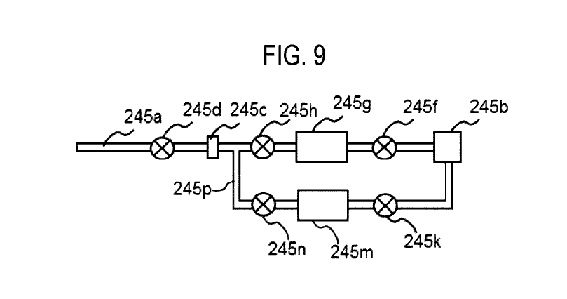

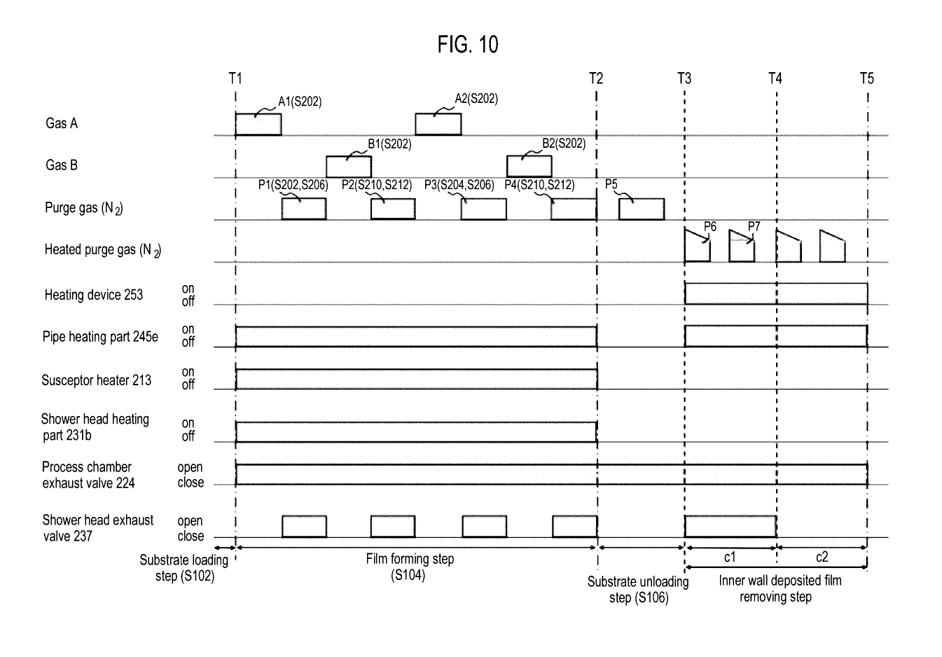

Subsequently, modification 2 of the present disclosure will be described with reference to FIGS. 9 and 10. Only a third gas supply system and a controller for controlling the third gas supply system illustrated in FIG. 9 in a substrate processing apparatus of modification 2 are different from the substrate processing apparatus of the first embodiment, and other components thereof are the same as those of the first embodiment.

As illustrated in FIG. 9, in the third gas supply system of modification 2, a first gas storage system and a second gas storage system are connected in parallel between the third gas supply source 245b and the MFC 245c in the third gas supply system 245 of the first embodiment. The first gas storage system is configured to include a valve 245f as an opening/closing valve, a tank 245g as a gas storage part for storing a gas and a valve 245h as an opening/closing valve. The second gas storage system is installed at a gas branch pipe 245p branched from the third gas supply pipe 245a and configured to include a valve 245k as an opening/closing valve, a tank 245m as a gas storage part for storing a gas, and a valve 245n as an opening/closing valve.

An operation of the third gas supply system of modification 2 will be described with reference to FIG. 10. A flow rate of the heated purge gas from the time T3 to the time T5 and a method for allowing the heated purge gas to be flown in FIG. 10 are different from those of FIG. 6 of the first embodiment, and other conditions of FIG. 10 are the same as those of FIG. 6. Further, the operation of the third gas supply system from the time T3 to the time T4 (first step c1) of modification 2 is the same as that of the third gas supply system from the time T3 to the time T4 (first step c1) of modification 1, and thus, a description thereof will be omitted.

As illustrated in P7 of FIG. 10, in modification 2, the heated purge gas from the third gas supply system 245 in the second step c2 of the deposited film removing step S110 is supplied into the buffer chamber 232 or the process chamber 201. At this time, at the time T4, the heated purge gas stored in the tank 245m of the third gas supply system 245 is supplied into the buffer chamber 232 at a time as the valve 245n is opened. The method for allowing this gas to be flown is referred to as Flush Flow. The valve 245d is already opened in P6 of FIG. 9. The capacity of the tank 245m is set such that an initial flow rate of the purge gas supplied into the buffer chamber 232 in P7 is greater than that of the heated purge gas in the first embodiment.

As illustrated in P7 of FIG. 10, the flow rate of the heated purge gas supplied into the buffer chamber 232 in P7, which is great when it is started to be supplied, is gradually reduced to be resultantly equal to that of the heated purge gas supplied into the buffer chamber 232 in the first embodiment. Also, the shape of P7 of FIG. 10 roughly indicates the flow rate, rather than being accurate.

In addition, storing of the heated purge gas in the tank 245m is performed by opening the valve 245k with the valve 245n closed, during the period till the time T4. Thereafter, after a predetermined amount of the heated purge gas is stored in the tank 245m, as described above, the valve 245m is opened at the timing of T4 of FIG. 10, so that the heated purge gas is supplied from the tank 245m into the buffer chamber 232 at a time. When P7 (second step c2) is terminated after a predetermined period of time, the valve 245n is closed and the heated purge gas is started to be stored in the tank 245m.

As described above, an operation of the third gas supply system in the first step c1 of modification 2 is the same as that of the third gas supply system in the first step c1 of modification 1. Also, since the operation of the third gas supply system in the film forming step S104 of modification 2 is performed in a state where the valve 245f and the valve 245h are opened, it is the same as the operation of the third gas supply system in the film forming step S104 of the first embodiment.

With the configuration as in modification 2, at least one of the following effects is provided.

(C1) Since it is configured such that the flow rate of the heated purge gas (inert gas) supplied to the shower head when it started to be supplied is greater than the flow rate of the purge gas when the supply of the purge gas is terminated in each of the first exhaust step and the second exhaust step, it is easy to remove the deposited film within the shower head and discharge the particles within the process chamber.

### (Modification 3)

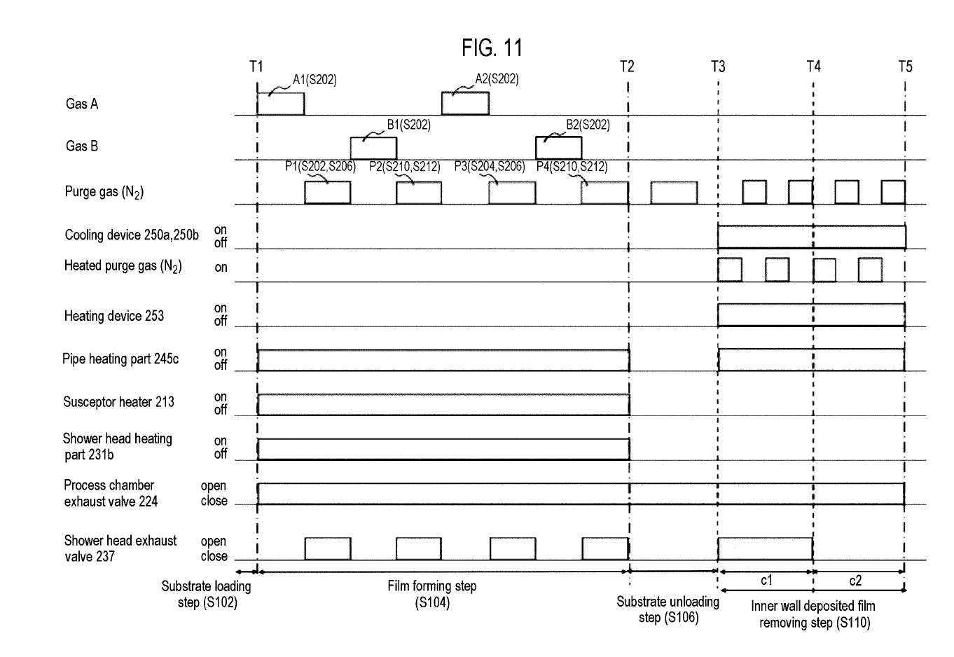

Subsequently, modification 3 of the present disclosure will be described with reference to FIGS. 1 and 11. A supply timing of a purge gas supplied into the process chamber of a substrate processing apparatus of modification 3 by controlling the first inert gas supply system, the second inert gas supply system, or the first inert gas supply system and the second inert gas supply system by a controller is different from that of the substrate processing apparatus of the first embodiment, and other components thereof are the same as those of the first embodiment.

Specifically, as illustrated in FIGS. 1 and 11, gas cooling devices 250a and 250b are installed in the first inert gas supply system and the second inert gas supply system, and a first inert gas, a second inert gas, or both of them as a coolant gas and the above-described heated purge gas are alternately supplied into the buffer chamber 232.

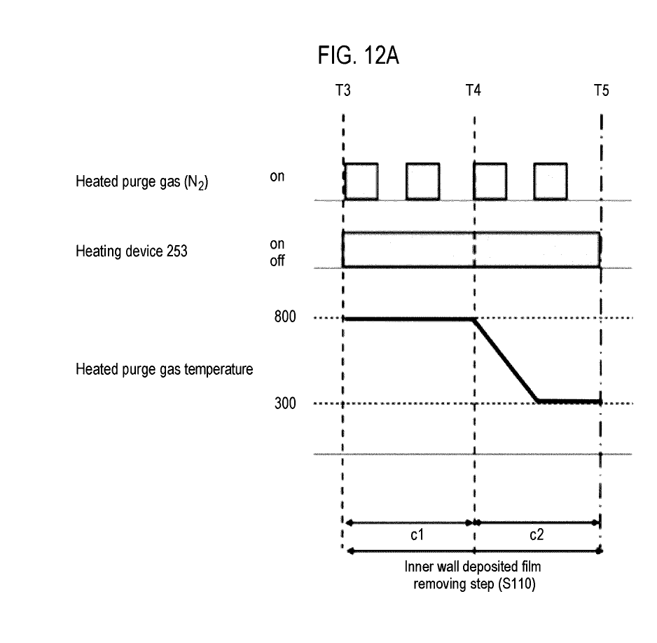

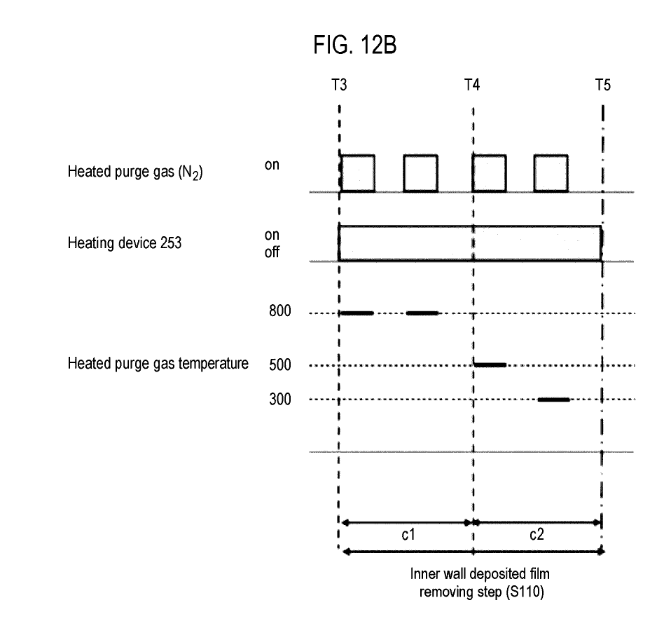

Preferably, as in FIGS. 12A and 12B described later, it may be configured such that the first inert gas and the second inert gas are directly supplied to the process chamber at a predetermined low temperature and the heated purge gas is directly supplied to the process chamber, while being gradually lowered in temperature. Further, it may also be configured such that the first inert gas and the second inert gas are directly supplied to the process chamber at a predetermined low temperature and the heated purge gas is directly supplied to the process chamber, while being gradually lowered in temperature a plurality of times by stages from a higher temperature to a lower temperature.

It may also be configured such that the first inert gas and the second inert gas are directly supplied to the process chamber, while being gradually increased in temperature from a low temperature, and the heated purge gas is directly supplied to the process chamber, while being gradually lowered in temperature.

It may also be configured such that the first inert gas and the second inert gas are directly supplied to the process chamber, while being increased in temperature a plurality of times by stages from a low temperature, and the heated purge gas is directly supplied to the process chamber, while being gradually lowered in temperature a plurality of times by stages from a higher temperature to a lower temperature.

It may also be configured such that the first inert gas and the second inert gas are directly supplied to the process chamber, while being increased in temperature a plurality of times by stages from a low temperature, and the heated purge gas is directly supplied to the process chamber, while being gradually lowered in temperature, and it may also be configured such that the first inert gas and the second inert gas are directly supplied to the process chamber, while being gradually increased in temperature from a low temperature, and the heated purge gas is directly supplied to the process chamber, while being lowered in temperature a plurality of times by stages from a higher temperature to a low temperature.

Also, it is preferred that the temperature of the heated purge gas in a termination stage of the deposited film removing step is controlled to be higher than that of the inert gas supplied in the film forming step, but the present disclosure is not limited thereto and the temperature of the heated purge gas in a termination stage of the deposited film removing step may be controlled to be equal to that of the inert gas supplied in the film forming step.

With the configuration as in modification 3, at least one of the following effects is provided.

(D1) By alternately supplying the first inert gas, the second inert gas, or both of them as a cooling gas and the heated purge gas, it is possible to give greater thermal stress to the deposited film deposited on the inner wall of the buffer chamber 232 or the dispersion plate 234, removing the deposited film more effectively.

(D2) By controlling a supply temperature of the heated purge gas to be decreased and finally equal to that of the cooling gas, it is possible to improve the throughput.

(D3) By making the difference in temperature between the first inert gas and the second inert gas and the heated purge gas large at an initial stage, it is possible to apply great thermal stress to the deposited film, and after the great thermal stress is applied to the deposited film at the initial stage, since a crack or the like occurs in the deposited film or a thick film or the like is removed, it is possible to remove the deposited film even with thermal stress smaller than that at the initial stage, and since less damage can be done to the components of the process chamber, it is possible to give thermal stress smaller than that at the initial stage to the deposited film or the like by making the temperature difference smaller than that at the initial stage.

(D4) Since the temperature of the process chamber is lowered as the temperature of the heated purge gas is lowered compared with that at the initial stage, it is possible to quickly proceed to a next processing step, promoting the improvement of throughput.

### (Modification 4)

Next, modification 4 of the present disclosure will be described with reference to FIGS. 12A and 12B. A substrate processing apparatus of modification 4 is different from the substrate processing apparatus of the first embodiment, in that the gas heating device 253 is controlled such that the temperature of the heated purge gas supplied into the shower head 230 in the deposited film removing step is different from the temperatures when the supply of the purge gas is started and when the supply of the purge gas is terminated, and other components thereof are the same as those of the first embodiment.

Specifically, as illustrated in FIGS. 12A and 12B, after the heated purge gas (about 800 degrees C. in FIG. 12A) heated by the gas heating device 253 at a temperature ranging from 400 to 1000 degrees C. in the deposited film removing step is supplied for a predetermined period of time (from a time T3 to a time T4 in FIG. 12A), the gas heating device 253 is controlled such that the temperature of the heated purge gas is gradually lowered to reach a temperature ranging from 300 to 400 degrees C. (about 300 degrees C. in FIG. 12A) near the internal temperature of the process chamber in the substrate loading step.

Further, in FIG. 12A, for convenience sake, the temperature of the heated purge gas is described to be changed continuously, but the present disclosure is not limited thereto and, as illustrated in FIG. 12B, the temperature of the heated purge gas may be controlled to be lowered a plurality of times by stages at every supply timing of the purge gas.

Here, the gas heating device 253 may be controlled by using a predetermined time lapse as a trigger or by using the supply of a predetermined number of supply times as a trigger at the timing at which the temperature of the heated purge gas is lowered. In addition, it is preferred that the temperature of the heated purge gas after the lowering of the temperature is controlled to be higher than that of the inert gas supplied in the film forming step, but the present disclosure is not limited thereto and the temperature of the heated purge gas may be controlled to be equal to that of the inert gas supplied in the film forming step.

With the configuration as in modification 4, at least one of the following effects is provided.

(E1) By performing the controlling in this manner, it is possible to quickly proceed to a next processing step, promoting the improvement of throughput in the substrate processing.

### Second Embodiment

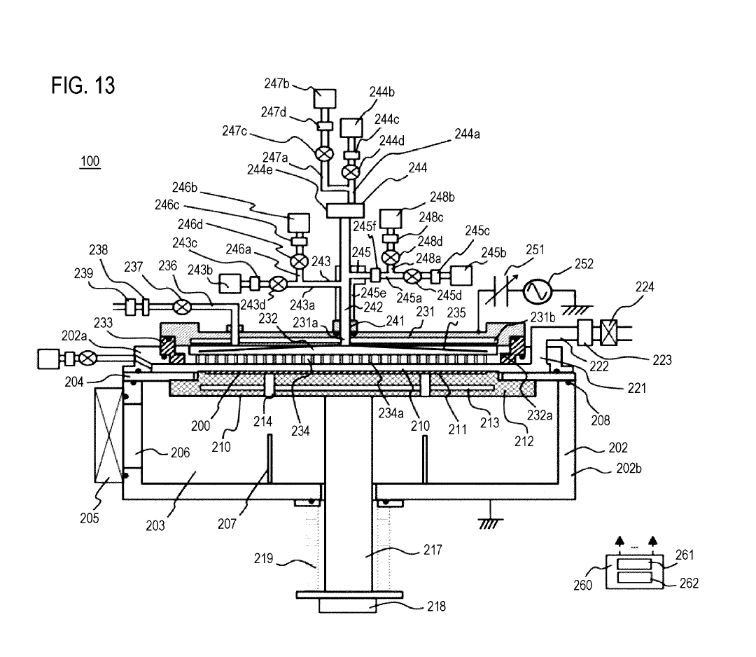

Next, a second embodiment of the present disclosure will be described with reference to FIG. 13. A substrate processing apparatus of the second embodiment is different from the substrate processing apparatus of the first embodiment, in that each of the first gas supply system, the second gas supply system, and the third gas supply system illustrated in FIG. 13 is connected to a common gas supply pipe 242 to supply a gas into the buffer chamber 232, and other components thereof are the same as those of the first embodiment.

As illustrated in FIG. 13, since the downstream ends of the first gas supply system 243, the second gas supply system 244, and the third gas supply system 245 are connected to the common gas supply pipe 242, it is possible to reduce the number of components of the substrate processing apparatus and costs, and also to facilitate the maintenance of the substrate processing apparatus.

With the configuration as in the second embodiment, at least one of the following effects is provided.

(F1) since it is possible to supply all of the gases by the common gas supply pipe 242, it is possible to reduce the number of components of the substrate processing apparatus, thereby reducing costs.

(F2) Since only the common gas supply pipe 242 needs to be repaired, the maintenance is facilitated.

### Third Embodiment

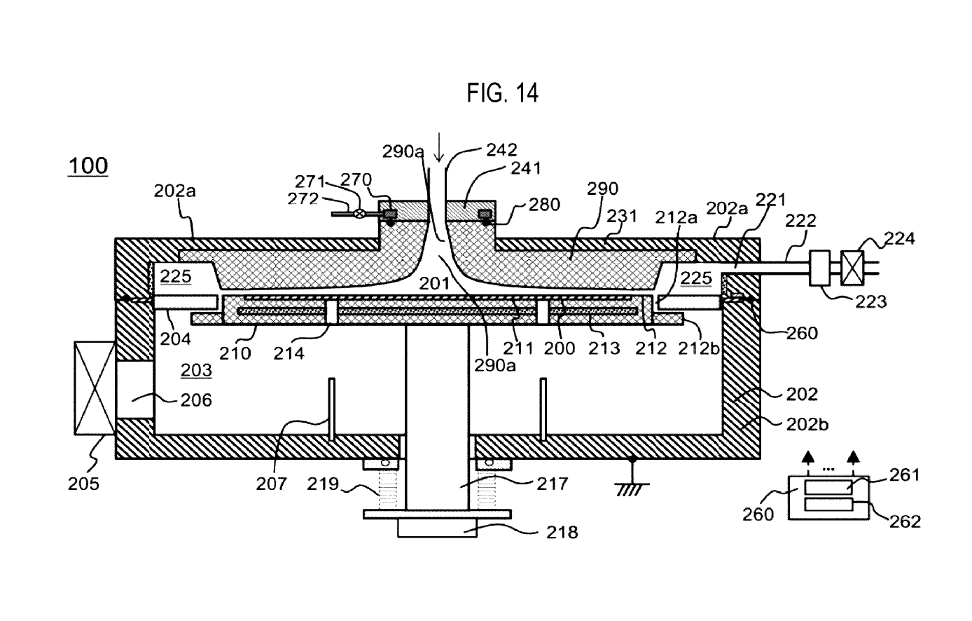

Subsequently, a third embodiment of the present disclosure will be described with reference to FIG. 14. A substrate processing apparatus of the third embodiment is different from those of the first and second embodiments, in that, as illustrated in FIG. 14, a gas rectifying part 290, instead of the shower head 230 in the first and second embodiments, is installed between the gas introduction part 241 and the process chamber 201, and other components thereof are the same as those of the first embodiment.

As illustrated in FIG. 14, the gas rectifying part 290 has a gas dispersion channel 290a for supplying a gas at the center of the gas rectifying part 290, and has a shape of an oval curved line (arc) drawn such that a lower surface of the gas rectifying part 290 is closed to the substrate in a direction toward the periphery of the substrate from the center of the substrate. The gas rectifying part 290 is installed on the lid 231 such that it is positioned between the gas introduction part 241 and the process chamber 201 through which the gas exists.

With the configuration as in the third embodiment, at least one of the following effects is provided.

(G1) Even though the substrate processing apparatus does not have a shower head, it is possible to effectively remove a deposited film and the maintenance of a device is facilitated.

### Fourth Embodiment

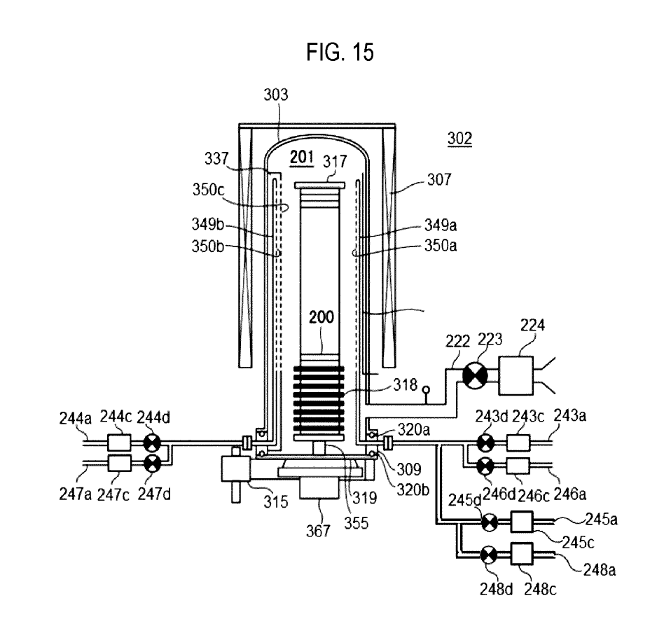

Subsequently, a fourth embodiment of the present disclosure will be described with reference to FIG. 15. A substrate processing apparatus of the fourth embodiment is different from those of first, second, and third embodiments, in that, as illustrated in FIG. 15, the substrate processing apparatus of the fourth embodiment is a vertical apparatus which processes a substrate to be processed by maintaining it in a stacked multi-stage. Further, the film formation conditions may be the same as those described above, but may also be appropriately modified into the conditions optimal for the vertical apparatus. In this embodiment, the same reference numerals will be used for the components for performing the same operations as those of the respective embodiments described above, and a description thereof will be omitted.

As illustrated in FIG. 15, a processing furnace 302 includes a reaction tube 303 constituting a reaction vessel (process vessel). The reaction tube 303 is made of a heat resistant material such as, for example, quartz (SiO₂) or silicon carbide (SiC), and has a cylindrical shape with its upper end closed and its lower end opened. The process chamber 201 is defined in a hollow cylindrical portion of the reaction tube 303. The process chamber 301 is configured to accommodate wafers 200 as substrates, in a state where horizontally-positioned wafers 200 are vertically aligned in multiple stages in a boat 317 described later.

A seal cap 319 as a lid for furnace opening configured to hermetically seal a lower end opening of the reaction tube 303 is installed under the reaction tube 303. The seal cap 319 is configured to contact the lower end of the reaction tube 303 from the lower side of the reaction tube 303 in the vertical direction. The seal cap 319 is made of metal such as, for example, stainless and has a disc shape. O-rings 320a and 320b, which are a seal member in contact with the lower end of the reaction tube 303, are installed at an upper surface of the seal cap 319. A rotation mechanism 367 configured to rotate the boat 317 as a substrate support described later is installed at a side of the seal cap 319 opposite to the process chamber 201. A rotary shaft 355 of the rotation mechanism 367 extends through the seal cap 319 and is connected to the boat 317. The rotation mechanism 367 is configured to rotate the wafers 200 by rotating the boat 317. The seal cap 319 is configured to vertically be elevated or lowered by a boat elevator 315, which is an elevation mechanism vertically disposed at the outside of the reaction tube 303, enabling the boat 317 to be loaded into or unloaded from the process chamber 201.

The boat 317, which is used as the substrate support, is made of a heat resistant material such as, for example, quartz or silicon carbide and configured to support a plurality of wafers 200, in a state where horizontally-positioned wafers 200 are vertically stacked in multiple stages, i.e., being separated from each other, with the centers of the wafers 200 aligned with each other. In addition, a heat insulating member 318 made of a heat resistant material such as, for example, quartz or silicon carbide, is installed at a lower portion of the boat 317, so that heat from the heater 307 described later is difficult to be transferred to the seal cap 319. Further, the heat insulating member 318 is configured by a plurality of heat insulating plates made of a heat-resistant material such as quartz or silicon carbide, and a heat insulating plate holder horizontally supporting these heat insulating plates in a multi-stage manner.

The processing furnace 302 has a heater 307 as a heating part (heating mechanism). The heater 307 has a cylindrical shape and is supported by a heater base (not shown) as a support plate so as to be vertically installed in a concentric shape with the reaction tube 303. Also, the heater 307 serves as an activation mechanism for activating a gas by heat as described hereinafter.

A first nozzle 349a as a first gas introduction part and a second nozzle 349b as a second gas introduction part are installed below the reaction tube 303 within the process chamber 201 to pass through a lower side wall of the reaction tube 303 or a sidewall surface of a manifold (not shown). The first gas supply pipe 243a, the first inert gas supply pipe 246a, the third gas supply pipe 245a, and a cleaning gas supply pipe 248a are connected to the first nozzle 233a, and the second gas supply pipe 244a and the second inert gas supply pipe 247a are connected to the second nozzle 349b.

The first nozzle 349a is installed to be lifted upwardly in a mounting direction of the wafer 200 along an upper portion from a lower portion of the inner wall of the reaction tube 303 in an annular space between the inner wall of the reaction tube 303 and the wafer 200. That is, the first nozzle 349a is installed on a side of a wafer arrangement region in which the wafer 200 is arranged. The first nozzle 349a is configured as a long nozzle having an L shape. A gas supply hole 350a for supplying a gas is installed on a side surface of the first nozzle 349a. The gas supply hole 350a is open toward the center of the reaction tube 303, so that it can supply a gas toward the wafer 200. A plurality of the gas supply holes 350a are installed to extend from a lower portion to an upper portion of the reaction tube 303, have the same opening area, and have the same opening pitch.

The second nozzle 349b is installed in the buffer chamber 337 as a gas dispersion space. The buffer chamber 337 is installed in an annular space between the inner wall of the reaction tube 303 and the wafer 200, that is, in a portion extending from the lower portion to the upper portion of the inner wall of the reaction tube 303, and installed in a mounting direction of the wafer 200. That is, the buffer chamber 337 is installed on a side of the wafer arrangement region. A gas supply hole 350c for supplying a gas is installed at an end portion of a wall of the buffer chamber 337 adjacent to the wafer 200. The gas supply hole 350c is open toward the center of the reaction tube 303, so that the gas feed opening 350c can supply a gas toward the wafer 200. A plurality of the gas supply holes 350c are installed to extend from a lower portion to an upper portion of the reaction tube 303, have the same opening area, and have the same opening pitch.

The second nozzle 349b is installed at an end portion opposing the end portion where the gas supply hole 350c of the buffer chamber 337 is installed to be lifted upward in a mounting direction of the wafer 200 along an upper portion, rather than at a lower portion of the inner wall of the reaction tube 303. That is, the second nozzle 349b is installed on a side of the wafer arrangement region. The second nozzle 349b is configured as a long nozzle having an L shape. A gas supply hole 350b for supplying a gas is formed on a side surface of the second nozzle 349b. The gas supply hole 350b is open toward the center of the buffer chamber 337. Like the gas supply hole 350c of the buffer chamber 337, a plurality of the gas supply holes 350b are installed to extend from a lower portion to an upper portion of the reaction tube 303. When a differential pressure within the buffer chamber 337 and within the process chamber 201 is small, an opening area of each of the plurality of gas supply holes 350b may be the same opening area and at the same opening pitch from an upstream side (lower portion) to a downstream side (upper portion), whereas when the differential pressure is large, the opening area of each of the gas supply holes may be increased or an opening pitch of the gas supply holes may be reduced from the upstream side to the downstream side.

Within the buffer chamber 337, a first bar-shaped electrode having an elongated structure and a second bar-shaped electrode as a counter electrode, as a plasma generating device (not shown), may be disposed in a stacking direction of the wafer 200 from the lower portion to the upper portion of the reaction tube 303.

With the configuration as in the fourth embodiment, the following effect is provided.

(F1) Since a plurality of substrates can be processed at a time, it is possible to significantly improve the throughput.

The present disclosure has been described above with reference to the embodiments, but the embodiments and modifications described above are not limited thereto and may be appropriately combined or modified without departing the spirit of the present disclosure, and the effects thereof can be obtained.

For example, in the foregoing embodiments, the example in which the capacitively coupled plasma (CCP) is used to generate plasma has been described. However, the present disclosure is not limited thereto and any one of an inductively coupled plasma (ICP), an electron cyclotron resonance (ECR) plasma, a helicon wave excited (HWP) plasma, a surface wave plasma (SWP) may be used.

Further, for example, in the foregoing embodiments, the example in which a reactant is supplied after a precursor is supplied has been described. However, the present disclosure is not limited thereto and the supply order of the precursor and the reactant may be reversed. That is, after the reactant is supplied, the precursor may be supplied. It is possible to change a film quality or a composition ratio of a formed film by changing the supply order.

Also, in the foregoing embodiments or the like, the example in which the SiN film is formed on the wafer 200 has been described. However, the present disclosure is not limited thereto and may also be appropriately applied even to a case in which a Si-based oxide film such as a silicon oxide film (SiO film), a silicon oxycarbide film (SiOC film), a silicon oxycarbonitride layer (SiOCN film), or a silicon oxynitride film (SiON film) is formed on the wafer 200. For example, in addition to the above-described gas, by using a carbon (C)-containing gas such as a propylene (C₃H₆) gas, or a boron (B)-containing gas such as a boron trichloride (BCl₃), for example, an SiO film, an SiON film, an SiOCN film, an SiOC film, an SiCN film, an SiBN film, an SiBCN film, or the like may be formed through a film formation sequence described below. Also, the order of allowing each gas to be flown may be appropriately modified. Even in a case of performing the film formation, the film formation may be performed under the same processing conditions as those of the embodiments described above, and the same effects as those of the embodiments described above can be obtained.

(3DMAS→O₃)×n [symbol] SiO

(HCDS→NH₃→O₂)×n [symbol] SiON

(HCDS→C₃H₆→O₂→NH₃)×n [symbol] SiOCN

(HCDS→TEA→O₂)×n [symbol] SiOC

(HCDS→C₃H₆→NH₃)×n [symbol] SiCN

(HCDS→BCl₃→NH₃)×n [symbol] SiBN

(HCDS→C₃H₆→BCl3→NH₃)×n [symbol] SiBCN

In this case, as a reaction gas, a nitrous oxide (N₂O) gas, a nitrogen monoxide (NO) gas, a nitrogen dioxide (NO₂) gas, an ozone (O₃) gas, a nitrogen peroxide (H₂O₂) gas, a vapor (H₂O) gas, a carbon monoxide (CO) gas, a carbon dioxide (CO₂) gas, or the like, in addition to the O₂ gas, may also be used.

In addition, the present disclosure may also be appropriately applied even to a case in which a metal-based oxide film or a metal-based nitride film containing a metal element such as titanium (Ti), zirconium (Zr), hafnium (Hf), tantalum (Ta), niobium (Nb), aluminum (Al), molybdenum (Mo), or tungsten (W) is formed on the wafer 200. That is, the present disclosure may be appropriately applied even to a case in which a TiO film, a TiOC film, a TiOCN film, a TiON film, a TiN film, a ZrO film, a ZrOC film, a ZrOCN film, a ZrON film, a ZrN film, an HfO film, an HfOC film, an HfOCN film, an HfON film, an HfN film, a TaO film, a TaOC film, a TaOCN film, a TaON film, a TaN film, an NbO film, an NbOC film, an NbOCN film, an NbON film, an NbN film, an AlO film, an AlOC film, an AlOCN film, an AlON film, an AN film, an MoO film, an MoOC film, an MoOCN film, an MoON film, an MoN film, a WO film, a WOC film, a WOCN film, a WON film, and a WN film is formed on the wafer 200.

For example, the present disclosure may be appropriately applied even to a case in which a tetrakis (dimethylamino) titanium (Ti[N(CH₃)₂]₄, abbreviation: TDMAT) gas, a tetrakis (ethylmethylamino) hafnium (Hf[N(C₂H₅)(CH₃)]₄, abbreviation: TEMAH) gas, a tetrakis (ethylmethylamino) zirconium (Zr[N(C₂H₅)(CH₃]₄, abbreviation: TEMAZ) gas, a trimethylaluminum (Al(CH₃)₃, abbreviation: TMA) gas, a titanium tetrachloride (TiCl₄) gas, and a hafnium tetrachloride (HfCl₄) gas, or the like is used as a precursor gas, and a titanium oxide film (TiO film), a hafnium oxide film (HfO film), a zirconium oxide film (ZrO film), an aluminum oxide film (AlO film), an aluminum nitride film (AlN film), or the like is formed on the wafer 200 through a film formation sequence described below.

(TDMAT→O₂*)×n [symbol] TiO

(TEMAH→O₂*)×n [symbol] HfO

(TEMAZ→O₂*)×n [symbol] ZrO

(TMA→O₂*)×n [symbol] AlO

(TMA→NH₃*)×n [symbol] AlN

That is, the present disclosure may be appropriately applied to a case in which the interior of the process chamber 201 is purged after a process of forming a semiconductor-based film or a metal-based film is performed. A process sequence and process conditions of the film formation process may be the same as those of the film formation process appearing in the embodiments or modifications described above. Also, a process sequence and process conditions of the purging process after performing the film formation process may be the same as those of the purging process appearing in the embodiments or modifications described above. Even in these cases, the same effects as those of the foregoing embodiments are obtained.

Preferably, the recipe for use in the film forming process (program in which process procedures, process conditions, and the like are described) may be individually prepared (a plurality of things are prepared) based on contents of the substrate processing (a film type of a thin film to be formed, a composition ratio, a film quality, a film thickness, process procedures, process conditions, and the like), and previously stored in the memory device 121c via an electrical communication line or the external memory device 128. In addition, when various processes are initiated, preferably, the CPU 121a may appropriately select a suitable process recipe among the plurality of process recipes stored in the memory device 121c based on contents of the substrate processing. With this configuration, thin films having a variety of film types, composition ratios, film qualities, and film thicknesses can be formed with high versatility and high reproducibility in one substrate processing apparatus. In addition, since an operator's work load (a load of inputting process procedures or process conditions, or the like) can be lessened, it is possible to rapidly initiate various processes while avoiding an operational error.

The above-described process recipe is not limited to a newly prepared recipe and may be prepared, for example, by modifying an existing recipe that is already installed on the substrate processing apparatus. When the process recipe is modified, the recipe after modification may be installed on the substrate processing apparatus via an electrical communication line or a recording medium in which the corresponding recipe is recorded. In addition, the existing recipe that is already installed on the substrate processing apparatus may be directly modified/changed by manipulating the input/output device 122 of the existing substrate processing apparatus.

While certain embodiments have been described, these embodiments have been presented by way of example only, and are not intended to limit the scope of the disclosures. Indeed, the novel methods and apparatuses described herein may be embodied in a variety of other forms; furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus, comprising:
a gas supply part configured to supply at least one of a film-forming gas, a first inert gas, and a second inert gas supplied at a temperature higher than that of the first inert gas into a process chamber in which a substrate is processed; and
a control part configured to control the gas supply part to perform a film-forming process of supplying the film-forming gas and the first inert gas from the gas supply part into the process chamber to process the substrate, and to perform a deposited film removing process of directly supplying the second inert gas having a temperature higher than that of the first inert gas from the gas supply part to the process chamber, in a state where there is no substrate in the process chamber, to remove a deposited film deposited within the process chamber.

2. The apparatus of claim 1, wherein the second inert gas is supplied at a temperature to easily generate a crack on the deposited film to facilitate a delamination, by generating a temperature gradient between the deposited film and a base member of the deposited film, a temperature of the deposited film being higher than a temperature of the base member.

3. The apparatus of claim 2, wherein the temperature gradient ranges from 50 to 200 degrees C.

4. The apparatus of claim 1, wherein the control part is configured to control the gas supply part to alternately supply the first inert gas and the second inert gas, the first inert gas having a temperature lower than that of the second inert gas.

5. The apparatus of claim 1, wherein a temperature of the second inert gas when the deposited film removing process is terminated is lower than a temperature when the deposited film removing process is started.

6. The apparatus of claim 1, wherein a temperature of the second inert gas gradually decreases from a time when the deposited film removing process is started to a time when the deposited film removing process is terminated.

7. The apparatus of claim 1, further comprising:
a first heating device configured to heat the process chamber;
a second heating device configured to heat the second inert gas; and
a third heating device configured to heat a gas supplied in at least the film-forming process.

8. A substrate processing apparatus, comprising:
a gas supply part configured to supply at least one of a film-forming gas, a first inert gas, and a second inert gas supplied at a temperature higher than that of the first inert gas into a process chamber in which a substrate is processed;
a memory device configured to store a program for processing at least the substrate;
an arithmetic part configured to read the program from the memory device; and
a control part including at least the memory device and the arithmetic part,
wherein the control part is configured to perform a film-forming process of the substrate by controlling the gas supply part such that the film-forming gas and the first inert gas are supplied into the process chamber through the program read from the memory device by the arithmetic part, and to perform a deposited film removing process of controlling the gas supply part to directly supply the second inert gas to the process chamber through the program read from the memory device by the arithmetic part, in a state where there is no substrate in the process chamber, to remove a deposited film deposited within the process chamber.

9. The apparatus of claim 8, wherein the second inert gas is supplied at a temperature making it easy to cause a crack in the deposited film to facilitate delamination, by generating a temperature gradient between the deposited film and a base member of the deposited film, a temperature of the deposited film being higher than that of the base member.

10. The apparatus of claim 9, wherein the temperature gradient ranges from 50 to 200 degrees C.

11. The apparatus of claim 8, wherein the control part is configured to control the gas supply part to alternately supply the first inert gas and the second inert gas, the first inert gas having a temperature lower than that of the second inert gas.

12. The apparatus of claim 8, wherein a temperature of the second inert gas when the deposited film removing process is terminated is lower than a temperature when the deposited film removing process is started.

13. The apparatus of claim 8, wherein a temperature of the second inert gas gradually decreases from a time when the deposited film removing process is started to a time when the deposited film removing process is terminated.

14. The apparatus of claim 8, further comprising:
a first heating device configured to heat the process chamber;
a second heating device configured to heat the second inert gas; and
a third heating device configured to heat a gas supplied from at least the film-forming process.

15. A non-transitory computer-readable storage medium storing a program that causes a computer to perform a process of:
supplying a film-forming gas and a first inert gas onto a substrate within a process chamber to form a film on the substrate; and
directly supplying a second inert gas having a temperature higher than that of the first inert gas into the process chamber, in a state where there is no substrate within the process chamber, to remove a deposited film deposited within the process chamber.
